(19) United States
(12) Patent Application Publication
(10) Pub. No.: US 2026/0285165 A1
(43) Pub. Date: Sep. 24, 2026

(54) SIGNAL GENERATION CIRCUIT, DRIVE CIRCUIT, POWER CONVERSION DEVICE, AND VEHICLE

(71) Applicant: ROHM CO., LTD., Kyoto-shi (JP)

(72) Inventors: Yohei NAKAMURA, Kyoto-shi, Kyoto (JP); Atsushi YAMAGUCHI, Kyoto-shi, Kyoto (JP); Junichi KASHIWAGI, Kyoto-shi, Kyoto (JP)

(21) Appl. No.: 19/688,825

(22) Filed: May 27, 2026

Related U.S. Application Data
(63) Continuation of application No. PCT/JP2024/040701, filed on Nov. 15, 2024.

(30) Foreign Application Priority Data
Dec. 5, 2023 (JP) 2023-205478

(51) Int. Cl. B60L 15/08; H02M 1/084; H02M 7/219; H03K 17/06; H03K 19/20

(52) U.S. Cl. CPC B60L 15/08; H02M 1/084; H02M 7/219; H03K 17/06; H03K 19/20; B60L 2210/42; B60L 2240/526

(57) ABSTRACT

A signal generation circuit according to one embodiment includes a delay signal generation unit configured to generate at least one delayed pulse signal using a common input pulse signal for a first switching element and a second switching element, and a logic synthesis unit configured to generate a first control pulse signal and a second control pulse signal for the first switching element and the second switching element by performing different logic synthesis operations on two signal sets among a plurality of signal sets defined by the at least one delayed pulse signal and the input pulse signal, wherein the first control pulse signal is different from the input pulse signal, and the second control pulse signal is different from the input pulse signal and the first control pulse signal.

### CROSS REFERENCE TO RELATED APPLICATIONS

This application is a continuation under 35 U.S.C. § 120 of PCT Application No. PCT/JP 2024/040701, filed on Nov. 15, 2024, which claims the benefit of priority from Japanese Patent Application No. 2023-205478, filed on Dec. 5, 2023. The entire contents of the above listed PCT application and priority application are incorporated herein by reference.

### TECHNICAL FIELD

The present invention relates to a signal generation circuit, a drive circuit, a power conversion device, and a vehicle.

### BACKGROUND

Patent Literature 1 (Japanese Patent No. 6468363) discloses a technology in which a parallel circuit of a first switching element that is a Si-IGBT and a second switching element that is a SiC-MOSFET is used in a switch unit constituting an inverter (see Patent Literature 1). The first switching element and the second switching element are driven by a first switching control signal (gate drive signal) and a second switching control signal (gate drive signal) that are different from each other. In order to generate the first switching control signal (gate drive signal) and the second switching control signal (gate drive signal) that are different from each other, an inverter control device including a microcomputer had to generate and output different switching control source signals for the first switching control signal and the second switching control signal.

### BRIEF DESCRIPTION OF DRAWINGS

FIG. 1 is a schematic diagram of a system configuration of a power conversion device to which a signal generation circuit according to a first embodiment is applied.

FIG. 2 is a circuit diagram for explaining a schematic configuration of an example of a switch unit and a drive circuit.

FIG. 3 is a time chart of various signals in the first embodiment.

FIG. 4 is a circuit diagram of a circuit used in a double pulse test in Experimental Example 1.

FIG. 5 is a graph showing measurement results of a gate voltage corresponding to a first gate signal and a gate voltage corresponding to a second gate signal at turn-on in Experimental Example 1.

FIG. 6 is a graph showing measurement results of a device current flowing through the first switching element and a device current flowing through the second switching element at turn-on in Experimental Example 1.

FIG. 7 is a graph showing measurement results of a gate voltage corresponding to a first gate signal and a gate voltage corresponding to a second gate signal at turn-off in Experimental Example 1.

FIG. 8 is a graph showing measurement results of a device current flowing through the first switching element and a device current flowing through the second switching element at turn-off in Experimental Example 1.

FIG. 9 is a circuit diagram of a drive circuit including a signal generation circuit according to a second embodiment.

FIG. 10 is a time chart of various signals in the second embodiment.

FIG. 11 is a circuit diagram of a circuit used in a double pulse test in Experimental Example 2.

FIG. 12 is a graph showing measurement results of a gate voltage corresponding to a first gate signal and a gate voltage corresponding to a second gate signal at turn-on in Experimental Example 2.

FIG. 13 is a graph showing measurement results of a device current flowing through the first switching element and a device current flowing through the second switching element at turn-on in Experimental Example 2.

FIG. 14 is a graph showing measurement results of a gate voltage corresponding to a first gate signal and a gate voltage corresponding to a second gate signal at turn-off in Experimental Example 2.

FIG. 15 is a graph showing measurement results of a device current flowing through the first switching element and a device current flowing through the second switching element at turn-off in Experimental Example 2.

FIG. 16 is a circuit diagram of a drive circuit including a signal generation circuit according to a third embodiment.

FIG. 17 is a time chart of various signals in the third embodiment.

FIG. 18 is a circuit diagram for explaining a fourth embodiment.

FIG. 19 is a circuit diagram for explaining a fifth embodiment.

FIG. 20 is a circuit diagram for explaining a sixth embodiment.

FIG. 21 is a diagram for explaining a modification of the sixth embodiment.

FIG. 22 is a circuit diagram for explaining a seventh embodiment.

FIG. 23 is a diagram showing a configuration example of a vehicle on which the power conversion device is mounted.

FIG. 24 is a schematic diagram of an example of a switch unit.

FIG. 25 is a schematic diagram of another example of a switch unit.

### DETAILED DESCRIPTION

Embodiments of the present disclosure will be described with reference to the drawings. In the description of the drawings, the same elements are denoted by the same reference numerals, and duplicate descriptions are omitted.

### First Embodiment

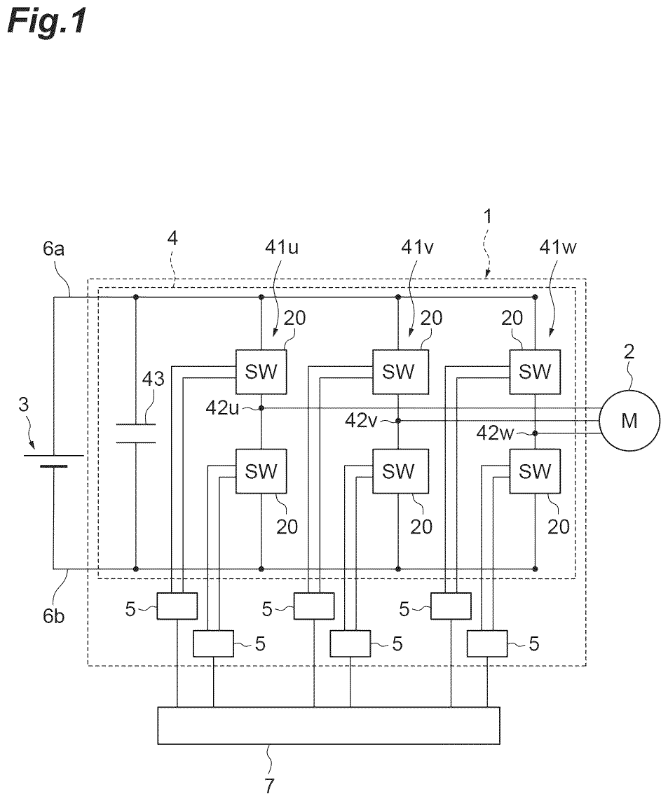

FIG. 1 is a schematic diagram of a system configuration of a power conversion device to which a signal generation circuit according to the first embodiment is applied. The power conversion device 1 is a device that converts power between direct current and alternating current. The power conversion device 1 is mounted on, for example, a vehicle such as a hybrid vehicle or an electric vehicle. The alternating current may be single-phase or multi-phase alternating current. Unless otherwise stated, the following description assumes an embodiment in which the power conversion device 1 is mounted on the above-described vehicle and the alternating current is three-phase alternating current.

As shown in FIG. 1, the power conversion device 1 is disposed between a motor (rotating electrical machine) 2 driven by alternating current and a DC power supply unit 3. The power conversion device 1 is configured to convert DC power from the DC power supply unit 3 into AC power to drive the motor 2. The power conversion device 1 is configured to be capable of converting AC power generated by the motor 2 into DC power for regeneration.

The DC power supply unit 3 includes a high-voltage DC power supply. An example of the rated voltage of the DC power supply unit 3 is 300 V or more and 900 V or less. The DC power supply unit 3 may be configured to be capable of storing electricity. Examples of the DC power supply unit 3 include a secondary battery, an electric double-layer capacitor, and the like. Examples of the secondary battery include a nickel-metal hydride secondary battery, a lithium-ion secondary battery, and the like. The DC power supply unit 3 may be a battery in which a secondary battery and an electric double-layer capacitor are combined. The DC power supply unit 3 may be an all-solid-state battery. The DC power supply unit 3 may include a DC/DC converter.

The motor 2 functions as, for example, a driving force source for a vehicle such as a hybrid vehicle or an electric vehicle. The motor 2 functions as an electric motor and also as a generator.

The power conversion device 1 includes an inverter circuit 4 and a plurality of drive circuits 5.

The inverter circuit 4 has a leg 41u, a leg 41v, and a leg 41w. The leg 41u is a U-phase leg, the leg 41v is a V-phase leg, and the leg 41w is a W-phase leg. The three legs 41u, 41v, and 41w are connected in parallel between a high-potential line 6a electrically connected to the positive electrode of the DC power supply unit 3 and a low-potential line 6b electrically connected to the negative electrode of the DC power supply unit 3.

Each of the leg 41u, the leg 41v, and the leg 41w has an upper-arm switch unit 20 and a lower-arm switch unit 20. Therefore, the inverter circuit 4 shown in FIG. 1 has six switch units 20. The two switch units 20 included in each of the legs 41u, 41v, and 41w are configured to be switched between an ON state, which is a conductive state, and an OFF state, which is a non-conductive state.

The two switch units 20 included in each of the legs 41u, 41v, and 41w are connected in series between the high-potential line 6a and the low-potential line 6b.

A node (connection point) 42u between the upper-arm switch unit 20 and the lower-arm switch unit 20 of the leg 41u is an AC input/output point and is electrically connected to the U-phase electrode of the motor 2.

A node (connection point) 42v between the upper-arm switch unit 20 and the lower-arm switch unit 20 of the leg 41v is an AC input/output point and is electrically connected to the V-phase electrode of the motor 2.

A node (connection point) 42w between the upper-arm switch unit 20 and the lower-arm switch unit 20 of the leg 41w is an AC input/output point and is electrically connected to the W-phase electrode of the motor 2.

The power conversion device 1 may have a capacitor 43 for smoothing the DC voltage supplied from the DC power supply unit 3 to the inverter circuit 4. The capacitor 43 is connected in parallel with the legs 41u, 41v, and 41w between the high-potential line 6a and the low-potential line 6b.

The plurality of drive circuits 5 are provided corresponding to the two switch units 20 included in each of the leg 41u, the leg 41v, and the leg 41w. Therefore, in the form shown in FIG. 1, the power conversion device 1 has six drive circuits 5. The six drive circuits 5 drive the switch units 20 based on an input pulse signal from an external control device 7 and corresponding to each drive circuit 5. An example of the external control device 7 is an ECU (Electronic Control Unit) mounted on an automobile.

In the power conversion device 1, the six switch units 20 have the same configuration, and the six drive circuits 5 also have the same configuration. Therefore, one set of the switch unit 20 and the drive circuit 5 will be used as an example to describe the switch unit 20 and the drive circuit 5.

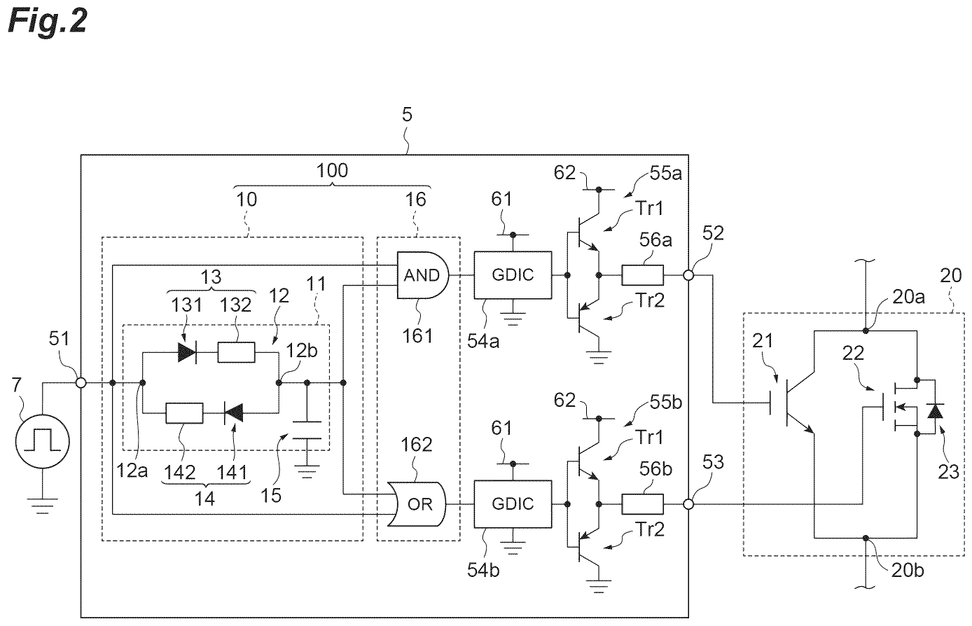

FIG. 2 is a circuit diagram for explaining a schematic configuration of an example of the switch unit 20 and the drive circuit 5.

### [Switch Unit]

The switch unit 20 has a first switching element 21 and a second switching element 22. The first switching element 21 and the second switching element 22 are connected in parallel between a node 20a and a node 20b of the switch unit 20.

When the switch unit 20 constitutes an upper arm, the node 20a of the upper-arm switch unit 20 is electrically connected to the high-potential line 6a, and the node 20b of the upper-arm switch unit 20 is electrically connected to the node 20a of the lower-arm switch unit 20.

When the switch unit 20 constitutes a lower arm, the node 20a of the lower-arm switch unit 20 is electrically connected to the node 20b of the upper-arm switch unit 20, and the node 20b of the lower-arm switch unit 20 is electrically connected to the low-potential line 6b.

Each of the first switching element 21 and the second switching element 22 is a semiconductor switching element configured to be switched between an ON state, which is a conductive state, and an OFF state, which is a non-conductive state.

Examples of semiconductor switching elements used for the first switching element 21 and the second switching element 22 include bipolar transistors, and unipolar transistors. An example of a bipolar transistor is an insulated gate bipolar transistor (IGBT). An example of a unipolar transistor is a metal-oxide-semiconductor field-effect transistor (MOSFET). The semiconductor switching elements may be power semiconductors. Examples of semiconductor materials for the semiconductor switching elements include silicon (Si), silicon carbide (SiC), and gallium nitride (GaN).

Each of the first switching element 21 and the second switching element 22 may be a semiconductor switching element obtained by a combination of a transistor type and a semiconductor material. For example, the first switching element 21 and the second switching element 22 may be Si-based IGBTs, Si-based MOSFETs, SiC-based IGBTs, or SiC-based MOSFETs.

The first switching element 21 and the second switching element 22 constituting the switch unit 20 are combined so that their characteristics differ from each other. In one embodiment, the first switching element 21 and the second switching element 22 differ in transition times between the ON state and the OFF state.

Unless otherwise stated, the following description assumes a case where the first switching element 21 is a Si-based IGBT (hereinafter referred to as “Si-IGBT”) and the second switching element 22 is a SiC-based MOSFET (hereinafter referred to as “SiC-MOSFET”). In this case, the second switching element 22 is a switching element having a shorter transition time between the ON state and the OFF state than the first switching element 21. In other words, the second switching element 22 is a switching element capable of higher-speed switching than the first switching element 21.

The first switching element 21 may be a bare chip of a Si-IGBT or may be an element in which the bare chip is housed in a package. The second switching element 22 may be a bare chip of a SiC-MOSFET or may be an element in which the bare chip is housed in a package.

The first switching element 21 has a first main terminal, a second main terminal, and a control terminal. When the first switching element 21 is a Si-IGBT, the first main terminal, the second main terminal, and the control terminal correspond to collector, emitter, and gate, respectively.

The second switching element 22 has a first main terminal, a second main terminal, and a control terminal. When the second switching element 22 is a SiC-MOSFET, the first main terminal, the second main terminal, and the control terminal correspond to drain, source, and gate, respectively.

As described above, unless otherwise stated, since the description assumes a case where the first switching element 21 is a Si-IGBT and the second switching element 22 is a SiC-MOSFET, the first main terminal, the second main terminal, and the control terminal of the first switching element 21 are referred to as collector, emitter, and gate, respectively, and the first main terminal, the second main terminal, and the control terminal of the second switching element 22 are referred to as drain, source, and gate, respectively.

The collector of the first switching element 21 and the drain of the second switching element 22 are electrically connected to the node 20a. The emitter of the first switching element 21 and the source of the second switching element 22 are electrically connected to the node 20b.

The gate of the first switching element 21 and the gate of the second switching element 22 are electrically connected to the drive circuit 5.

The switch unit 20 may have a freewheeling diode 23. The freewheeling diode 23 is connected in antiparallel with the second switching element 22. Specifically, the cathode of the freewheeling diode 23 is electrically connected to the drain (or node 20a) of the second switching element 22. The anode of the freewheeling diode 23 is electrically connected to the source (or node 20b) of the second switching element 22. A parasitic diode inside the SiC-MOSFET may be used as the freewheeling diode 23.

### [Drive Circuit]

The drive circuit 5 is a circuit that outputs a first gate signal (first drive pulse signal) for driving the first switching element 21 and a second gate signal (second drive pulse signal) for driving the second switching element 22, based on a common input pulse signal for the first switching element 21 and the second switching element 22. In FIG. 2, the external control device 7 that generates and outputs the input pulse signal is schematically illustrated as a pulse signal source.

The drive circuit 5 has an input terminal 51 to which the input pulse signal is input, a first output terminal 52 that outputs the first gate signal, and a second output terminal 53 that outputs the second gate signal.

The input terminal 51 is electrically connected to the external control device 7.

The first output terminal 52 is electrically connected to the gate of the first switching element 21.

The second output terminal 53 is electrically connected to the gate of the second switching element 22.

The drive circuit 5 has a signal generation circuit 100, a first insulated gate driver IC (first driver) 54a, a first push-pull circuit 55a, a second insulated gate driver IC (second driver) 54b, and a second push-pull circuit 55b. The first insulated gate driver IC 54a and the second insulated gate driver IC 54b are referred to as a first GDIC 54a and a second GDIC 54b, respectively.

The signal generation circuit 100 is a circuit that generates a first control pulse signal for the first switching element 21 and a second control pulse signal for the second switching element 22 using the input pulse signal input to the input terminal 51. The first control pulse signal and the second control pulse signal are different signals generated from the common input pulse signal.

The first GDIC 54a is connected between a first power supply potential line 61 and ground. An example of the first power supply potential supplied to the first power supply potential line 61 is 5 V. The first GDIC 54a outputs a first output pulse signal based on the first control pulse signal. The first output pulse signal is a signal obtained by amplifying the first control pulse signal. In the present embodiment, the first output pulse signal is a signal that drives the first push-pull circuit 55a.

The first GDIC 54a has a function of transmitting a signal while isolating the signal generation circuit 100 from the first push-pull circuit 55a, and a function of amplifying the first control pulse signal. For example, the first GDIC 54a has an insulated signal transmission element and an amplifier. The insulated signal transmission element may be, for example, a photocoupler, a magnetic coupler using a transformer, or a capacitive coupler using a capacitor. The first GDIC 54a may have a protection circuit such as an undervoltage protection circuit or an overvoltage protection circuit.

The first push-pull circuit 55a has a first transistor Tr1 and a second transistor Tr2 connected in series between a second power supply potential line 62 and ground. The first push-pull circuit 55a is a totem-pole output stage in which the first transistor Tr1 and the second transistor Tr2 are connected in series.

In the present embodiment, the first transistor Tr1 is an npn transistor, and the second transistor Tr2 is a pnp transistor.

The collector of the first transistor Tr1 is connected to the second power supply potential line 62. An example of the second power supply potential supplied to the second power supply potential line 62 is +18 V.

The emitter of the first transistor Tr1 is connected to the emitter of the second transistor Tr2.

The collector of the second transistor Tr2 is connected to ground.

The gates of each of the first transistor Tr1 and the second transistor Tr2 are electrically connected to the first GDIC 54a, and the first output pulse signal is input from the first GDIC 54a.

The node between the emitter of the first transistor Tr1 and the emitter of the second transistor Tr2 is electrically connected to the first output terminal 52 via a first gate resistor 56a. That is, the first gate resistor 56a is disposed on the signal path between the node between the series-connected first transistor Tr1 and second transistor Tr2 and the first output terminal 52. An example of the resistance value of the first gate resistor 56a is 1 Ω or more and 100 Ω or less.

In the first push-pull circuit 55a having the above configuration, the first transistor Tr1 and the second transistor Tr2 are driven in response to the first output pulse signal from the first GDIC 54a. As a result, a first gate signal obtained by amplifying the first output pulse signal is obtained. The first gate signal is input to the first output terminal 52 via the first gate resistor 56a. Since the first output terminal 52 is electrically connected to the control terminal of the first switching element 21, the first gate signal is input to the gate (control terminal) of the first switching element 21.

The second GDIC 54b is connected between the first power supply potential line 61 and ground. The second GDIC 54b outputs a second output pulse signal based on the second control pulse signal. The second output pulse signal is a signal obtained by amplifying the second control pulse signal. In the present embodiment, the second output pulse signal is a signal that drives the second push-pull circuit 55b.

The second GDIC 54b has a function of transmitting a signal while isolating the signal generation circuit 100 from the second push-pull circuit 55b, and a function of amplifying the second control pulse signal. For example, the second GDIC 54b has an insulated signal transmission element and an amplifier. An example of the insulated signal transmission element may be a photocoupler, a magnetic coupler using a transformer, or a capacitive coupler using a capacitor. The second GDIC 54b may have a protection circuit such as an undervoltage protection circuit or an overvoltage protection circuit. Unless otherwise stated, the second GDIC 54b is also the same IC as the first GDIC 54a. However, the second GDIC 54b may be a different IC from the first GDIC 54a.

The second push-pull circuit 55b has a first transistor Tr1 and a second transistor Tr2 connected in series between the second power supply potential line 62 and ground. The second push-pull circuit 55b is a totem-pole output stage in which the first transistor Tr1 and the second transistor Tr2 are connected in series. In the present embodiment, the first transistor Tr1 and the second transistor Tr2 of the second push-pull circuit 55b are the same as those of the first push-pull circuit 55a. That is, the first transistor Tr1 is an npn transistor, and the second transistor Tr2 is a pnp transistor.

The collector of the first transistor Tr1 is connected to the second power supply potential line 62.

The emitter of the first transistor Tr1 is connected to the emitter of the second transistor Tr2.

The collector of the second transistor Tr2 is connected to ground.

The gates of each of the first transistor Tr1 and the second transistor Tr2 are electrically connected to the second GDIC 54b, and the second output pulse signal from the second GDIC 54b is input thereto.

The node between the emitter of the first transistor Tr1 and the emitter of the second transistor Tr2 is electrically connected to the second output terminal 53 via a second gate resistor 56b. That is, the second gate resistor 56b is disposed on the signal path between the node between the series-connected first transistor Tr1 and second transistor Tr2 and the second output terminal 53. An example of the resistance value of the second gate resistor 56b is the same as that of the first gate resistor 56a. The resistance value of the second gate resistor 56b may be the same as the resistance value of the first gate resistor 56a or may be different from the resistance value of the first gate resistor 56a.

In the second push-pull circuit 55b having the above configuration, the first transistor Tr1 and the second transistor Tr2 are driven in response to the second output pulse signal from the second GDIC 54b. As a result, a second gate signal obtained by amplifying the second output pulse signal is obtained. The second gate signal is input to the second output terminal 53 via the second gate resistor 56b. Since the second output terminal 53 is electrically connected to the control terminal of the second switching element 22, the second gate signal is input to the gate (control terminal) of the second switching element 22.

### [Signal Generation Circuit]

Next, the signal generation circuit 100 according to one embodiment will be described in detail. The signal generation circuit 100 has a delay signal generation unit 10 and a logic synthesis unit 16.

The delay signal generation unit 10 generates a delayed pulse signal that is delayed with respect to the input pulse signal. The delay signal generation unit 10 has a delay circuit 11 that generates the delayed pulse signal.

The delay circuit 11 is configured to be capable of setting a resistance value for delaying a rising edge of the input pulse signal and a resistance value for delaying a falling edge of the input pulse signal. The delay circuit 11 has a parallel circuit (resistance unit) 12 in which a first series circuit 13 and a second series circuit 14 are connected in parallel, and a capacitor 15.

The parallel circuit 12 has a node (first end) 12a and a node (second end) 12b. The node 12a is electrically connected to the input terminal 51. The input pulse signal is input to the node 12a from the external control device 7. The node 12b is electrically connected to the logic synthesis unit 16.

The first series circuit 13 is configured by connecting a first diode 131 and a first resistor 132 in series. The anode of the first diode 131 is connected to the node 12a. The first resistor 132 is connected between the cathode of the first diode 131 and the node 12b. An example of the forward voltage of the first diode 131 is 0.5 V or more and 1.0 V or less. An example of the resistance value of the first resistor 132 is 10 Ω or more and 10 kΩ or less.

The second series circuit 14 is configured by connecting a second diode 141 and a second resistor 142 in series. The anode of the second diode 141 is connected to the node 12b. The second resistor 142 is connected between the cathode of the second diode 141 and the node 12a. An example of the forward voltage of the second diode 141 is the same as that of the first diode 131. The second diode 141 may be the same as or different from the first diode 131. An example of the resistance value of the second resistor 142 is the same as that of the first resistor 132. The second resistor 142 may be the same as or different from the first resistor 132.

The capacitor 15 is connected between the node 12b and ground. An example of the capacitance of the capacitor 15 is 10 pF or more and 10 nF or less.

In the delay circuit 11, the first series circuit 13 functions as a signal path for delaying the rising edge of the input pulse signal, and the first series circuit 13 (specifically, the first resistor 132) and the capacitor 15 constitute a delay circuit that delays the rising edge of the input pulse signal. The delay time for the rising edge is determined by the resistance value of the first resistor 132 and the capacitance of the capacitor 15.

In the delay circuit 11, the second series circuit 14 functions as a signal path for delaying the falling edge of the input pulse signal, and the second series circuit 14 and the capacitor 15 constitute a delay circuit that delays the falling edge of the input pulse signal. The delay time for the falling edge is determined by the resistance value of the second resistor 142 and the capacitance of the capacitor 15.

The logic synthesis unit 16 is configured to include an AND circuit 161 for generating the first control pulse signal and an OR circuit 162 for generating the second control pulse signal.

The AND circuit 161 is electrically connected to the input terminal 51 and the delay signal generation unit 10. A signal set of the input pulse signal and the first delayed pulse signal is input to the AND circuit 161. The AND circuit 161 is a logical product circuit that outputs the first control pulse signal by performing a logical AND operation on the input pulse signal and the first delayed pulse signal that have been input. The AND circuit 161 is electrically connected to the first GDIC 54a, and the first control pulse signal output from the AND circuit 161 is input to the first GDIC 54a.

The OR circuit 162 is electrically connected to the input terminal 51 and the delay signal generation unit 10. A signal set of the input pulse signal and the first delayed pulse signal is input to the OR circuit 162. The OR circuit 162 is a logical sum circuit that outputs the second control pulse signal by performing a logical OR operation on the input pulse signal and the second delayed pulse signal that have been input. The OR circuit 162 is electrically connected to the second GDIC 54b, and the second control pulse signal output from the OR circuit 162 is input to the second GDIC 54b.

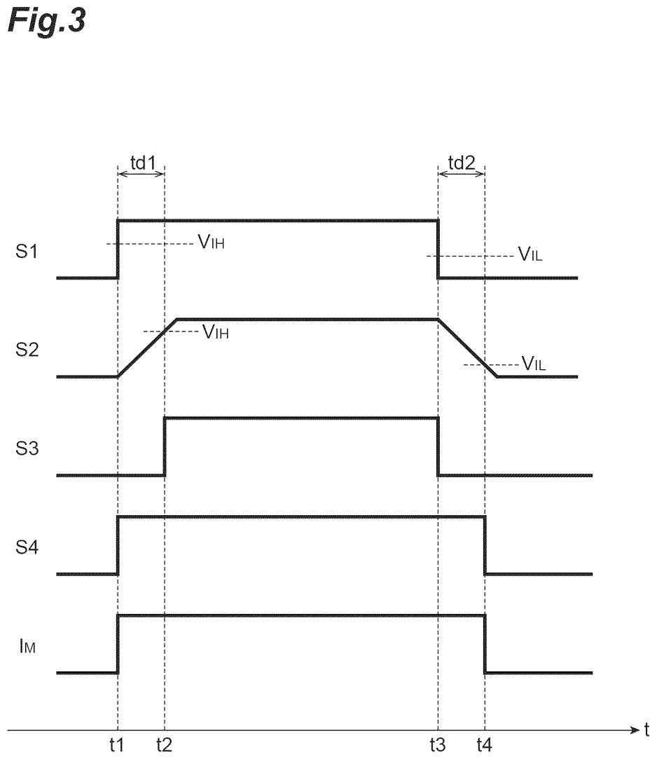

FIG. 3 is a time chart of various signals in the first embodiment. In FIG. 3, the input pulse signal, the delayed pulse signal, the first gate signal, the second gate signal, and the current of the main circuit (hereinafter referred to as “main circuit current”) are represented as input pulse signal S1, delayed pulse signal S2, first control pulse signal S3, second control pulse signal S4, and main circuit current I_{M}, respectively. The main circuit current I_{M} is the current flowing through the switch unit 20. Specifically, the main circuit current I_{M} is the current flowing between the node 20a and the node 20b.

In FIG. 3, the threshold voltage (threshold signal level) for regarding the input signal as High and the threshold voltage (threshold signal level) for regarding the input signal as Low in the AND circuit 161 and the OR circuit 162 are shown as V_{IH} and V_{IL}, respectively. In the AND circuit 161 and the OR circuit 162, once the input signal exceeds V_{IH}, it is regarded as a High state unless it falls below V_{IL}, and once the input signal falls below V_{IL}, it is regarded as a Low state unless it exceeds V_{IH} again. An example of V_{IH} is 3 V, and an example of V_{IL} is 2 V.

An example of the operation of the drive circuit 5 and the switch unit 20 will be described with reference to FIG. 2 and FIG. 3.

As shown in FIG. 3, the input pulse signal S1 has a pulse that rises at time t1 and falls at time t3. When the input pulse signal S1 is input to the delay signal generation unit 10, the delay signal generation unit 10 generates the delayed pulse signal S2.

The delay signal generation unit 10 has the parallel circuit 12 and the capacitor 15. The parallel circuit 12 has the first series circuit 13 that contributes to the delay of the rising edge and the second series circuit 14 that contributes to the delay of the falling edge. Therefore, as shown in FIG. 3, the delayed pulse signal S2 rises at time t2, which is after a delay time td1 from time t1, and falls at time t4, which is after a delay time td2 from time t3. “Rising after a delay time from a certain time (referred to as ‘time α’)” means that the signal level gradually rises from time α and exceeds a certain threshold level after the delay time. “Falling after a delay time from a certain time (referred to as ‘time β’)” means that the signal level gradually decreases from time β and falls below a certain threshold level after the delay time.

In the example shown in FIG. 3, the threshold level that determines the delay time for the rising edge is V_{IH}, which is the same as the threshold voltage for regarding a signal input to the AND circuit 161 and the OR circuit 162 as High, and the threshold level that determines the delay time for the falling edge is V_{IL}, which is the same as the threshold voltage for regarding a signal input to the AND circuit 161 and the OR circuit 162 as Low.

The delayed pulse signal S2 generated by the delay signal generation unit 10 is input to the logic synthesis unit 16. The logic synthesis unit 16 has the AND circuit 161 and the OR circuit 162. The AND circuit 161 performs a logical AND operation on the signal set of the input pulse signal S1 and the delayed pulse signal S2 to generate the first control pulse signal S3. The OR circuit 162 performs a logical OR operation on the signal set of the input pulse signal S1 and the delayed pulse signal S2 to generate the second control pulse signal S4.

In the example shown in FIG. 3, the signal level (voltage) of the input pulse signal S1 exceeds the threshold voltage V_{IH} at time t1 and falls below the threshold voltage V_{IL} at time t3. Therefore, the input pulse signal S1 input to the AND circuit 161 and the OR circuit 162 is processed in the AND circuit 161 and the OR circuit 162 as a signal that is in a High state from time t1 to time t3 and thereafter remains in a Low state until it exceeds the threshold voltage V_{IH} again.

The signal level (voltage) of the delayed pulse signal S2 exceeds the threshold voltage V_{IH} at time t2 and falls below the threshold voltage V_{IL} at time t4. Therefore, the delayed pulse signal S2 input to the AND circuit 161 and the OR circuit 162 is processed in the AND circuit 161 and the OR circuit 162 as a signal that is in a High state from time t2 to time t4 and thereafter remains in a Low state until it exceeds the threshold voltage V_{IH} again.

The first control pulse signal S3 is generated by the logical AND of the input pulse signal S1 and the delayed pulse signal S2. From the relationship between the above-described High and Low states of the input pulse signal S1 and the delayed pulse signal S2 in the AND circuit 161, the first control pulse signal S3 is a pulse signal that rises at time t2 and falls at time t3. The second control pulse signal S4 is generated by the logical OR of the input pulse signal S1 and the delayed pulse signal S2. From the relationship between the above-described High and Low states of the input pulse signal S1 and the delayed pulse signal S2 in the OR circuit 162, the second control pulse signal S4 is a pulse signal that rises at time t1 and falls at time t4.

In this way, the signal generation circuit 100 can generate the first control pulse signal S3 and the second control pulse signal S4, which have different delay states, based on the same input pulse signal S1.

In the drive circuit 5, the first control pulse signal S3 is input to the first GDIC 54a and is output therefrom as the first output pulse signal. The first output pulse signal output from the first GDIC 54a is input to the first push-pull circuit 55a and is output therefrom as the first gate signal. The first gate signal is input to the first output terminal 52 via the first gate resistor 56a. Since the first output terminal 52 is electrically connected to the gate of the first switching element 21, the first switching element 21 is driven by the first gate signal.

Since the first output pulse signal is a pulse signal obtained by amplifying the first control pulse signal, the first output pulse signal has the same waveform as the first control pulse signal. Since the first gate signal is a pulse signal obtained by amplifying the first output pulse signal, the first gate signal has the same waveform as the first output pulse signal. Therefore, the first gate signal has the same waveform as the first control pulse signal S3.

In the drive circuit 5, the second control pulse signal S4 is input to the second GDIC 54b and is output therefrom as the second output pulse signal. The second output pulse signal output from the second GDIC 54b is input to the second push-pull circuit 55b and is output therefrom as the second gate signal. The second gate signal is input to the second output terminal 53 via the second gate resistor 56b. Since the second output terminal 53 is electrically connected to the gate of the second switching element 22, the second switching element 22 is driven by the second gate signal.

Since the second output pulse signal is a pulse signal obtained by amplifying the second control pulse signal S4, the second output pulse signal has the same waveform as the second control pulse signal S4. Since the second gate signal is a pulse signal obtained by amplifying the second output pulse signal, the second gate signal has the same waveform as the second output pulse signal. Therefore, the second gate signal has the same waveform as the second control pulse signal S4.

Since the first switching element 21 is driven by the first gate signal having the same waveform as the first control pulse signal S3, the first switching element 21 turns on at time t2 and turns off at time t3. Since the second switching element 22 is driven by the second gate signal having the same waveform as the second control pulse signal S4, the second switching element 22 turns on at time t1 and turns off at time t4.

The timing at which the first switching element 21 turns on and the timing at which the second switching element 22 turns on are adjusted by the delay time td1. The delay time td1 [s] is expressed as the product of the resistance value R1 [Ω] and the capacitance C [F] when the resistance value of the first resistor 132 is R1 [Ω] and the capacitance of the capacitor 15 is C [F]. Therefore, by adjusting the resistance value R1 and the capacitance C, the timing at which the first switching element 21 turns on and the timing at which the second switching element 22 turns on can be adjusted.

The timing at which the first switching element 21 turns off and the timing at which the second switching element 22 turns off are adjusted by the delay time td2. The delay time td2 [s] is expressed as the product of the resistance value R2 [Ω] and the capacitance C [F] when the resistance value of the second resistor 142 is R2 [Ω]. Therefore, by adjusting the resistance value R2 and the capacitance C, the timing at which the first switching element 21 turns off and the timing at which the second switching element 22 turns off can be adjusted.

The switch unit 20 is configured by connecting the first switching element 21 and the second switching element 22 in parallel. Therefore, when either one of the first switching element 21 and the second switching element 22 is in the ON state, a path between the node 20a and the node 20b is in a conductive state. That is, when either one of the first switching element 21 and the second switching element 22 is in the ON state, the switch unit 20 is in the ON state.

On the other hand, when both the first switching element 21 and the second switching element 22 are in the OFF state, the path between the node 20a and the node 20b is in a non-conductive state. That is, when both the first switching element 21 and the second switching element 22 are in the OFF state, the switch unit 20 is in the OFF state. Therefore, the switch unit 20 is in the ON state from time t1 to time t4, and as shown in FIG. 3, the main circuit current I_{M} flows from time t1 to time t4.

As can be understood from the time chart of various signals shown in FIG. 3, by driving the switch unit 20 with the drive circuit 5 having the signal generation circuit 100, the second switching element 22, which is a SiC-MOSFET, is responsible for the turn-on and turn-off functions of the switch unit 20. Since the SiC-MOSFET has a shorter transition time between the ON state and the OFF state than the Si-IGBT, the transition time at turn-on and turn-off in the switch unit 20 can also be shortened. That is, the switch unit 20 can achieve high-speed switching similarly to the SiC-MOSFET.

As can be understood from the time chart of various signals shown in FIG. 3, when the switch unit 20 is driven by the drive circuit 5 having the signal generation circuit 100, the first switching element 21, which is a Si-IGBT, is also in the ON state from time t2 to time t3. The Si-IGBT has smaller conduction loss at a large current than the SiC-MOSFET and is resistant to overcurrent. Therefore, when the switch unit 20 turns on and a larger current begins to flow, the current mainly flows through the first switching element 21, so the resistance of the switch unit 20 to overcurrent is also improved.

The switch unit 20 of the power conversion device 1 is configured by connecting the first switching element 21 and the second switching element 22, which have different characteristics, in parallel. Therefore, in the configuration of the drive circuit 5, the first switching element 21 and the second switching element 22 can be driven so as to effectively utilize the respective characteristics of the first switching element 21 and the second switching element 22. Therefore, a switch unit 20 having superior characteristics can be realized compared to a case where the switch unit 20 is configured with only one of the first switching element 21 and the second switching element 22. As a result, the characteristics of the power conversion device 1 including the switch unit 20 are also improved.

When the switch unit 20 has the first switching element 21 and the second switching element 22, which have different characteristics, it is also conceivable to generate different first gate signals and second gate signals based on different input pulse signals for the first switching element 21 and the second switching element 22. In this case, a drive circuit that generates the first gate signal based on the input pulse signal corresponding to the first switching element 21 and a drive circuit that generates the second gate signal based on the input pulse signal corresponding to the second switching element 22 are required. In other words, two drive circuits are required for one switch unit 20. As a result, as shown in FIG. 1, when the power conversion device 1 has six switch units 20, the number of drive circuits included in the power conversion device 1 is twelve. When generating different first gate signals and second gate signals based on different input pulse signals for the first switching element 21 and the second switching element 22, the external control device 7 is configured to generate different input pulse signals for the switch unit 20 including the first switching element 21 and the second switching element 22. Therefore, for example, an existing external control device 7 for a case where the switch unit 20 is configured with either the first switching element 21 or the second switching element 22 cannot be used.

In contrast, the signal generation circuit 100 can generate the first control pulse signal and the second control pulse signal from a common input pulse signal for the first switching element 21 and the second switching element 22. Therefore, the drive circuit 5 including the signal generation circuit 100 can output the first gate signal and the second gate signal for driving the first switching element 21 and the second switching element 22. Thus, the number of drive circuits 5 for the switch unit 20 only needs to be one. As a result, as shown in FIG. 1, when the power conversion device 1 has six switch units 20, the number of drive circuits 5 included in the power conversion device 1 is six. Therefore, in the configuration of the drive circuit 5 having the signal generation circuit 100, the number of drive circuits 5 included in the power conversion device 1 can be reduced compared to the case where different input pulse signals are used for the first switching element 21 and the second switching element 22. Since the number of drive circuits 5 is small in this way, the manufacturing cost of the power conversion device 1 can be reduced.

Since the signal generation circuit 100 generates the first control pulse signal and the second control pulse signal from a common input pulse signal for the first switching element 21 and the second switching element 22, an existing external control device 7 can be used. Therefore, it is easy to apply the switch unit 20 to an existing external control device 7 and a device equipped with the same (for example, a hybrid vehicle, an electric vehicle, etc.). For example, when the switch unit of a power conversion device (or inverter) mounted on a hybrid vehicle, an electric vehicle, or the like is replaced with the switch unit 20, the switch unit 20 can be driven without changing the control program of the power conversion device in the ECU by setting the signal generation circuit 100 in the preceding stage of the existing GDIC.

The Si-IGBT is a lower-cost device than the SiC-MOSFET. Therefore, compared to a case where all the switching elements of the switch unit 20 are configured with SiC-MOSFETs, it is possible to reduce the manufacturing cost of the switch unit 20 and the manufacturing cost of the power conversion device 1 including the switch unit 20 while maintaining the characteristics of the SiC-MOSFET.

The delay circuit 11 has the parallel circuit 12 and the capacitor 15. The parallel circuit 12 is configured by connecting in parallel the first series circuit 13 that contributes to the delay of the rising edge of the input pulse signal and the second series circuit 14 that contributes to the delay of the falling edge of the input pulse signal. Therefore, the delay time td1 for the rising edge of the input pulse signal and the delay time td2 for the falling edge can be adjusted separately.

Specifically, as described above, the delay time td1 [s] is expressed as the product of the resistance value R1 [Ω] of the first resistor 132 and the capacitance C [F] of the capacitor 15, and the delay time td2 [s] is expressed as the product of the resistance value R2 [Ω] of the second resistor 142 and the capacitance C [F] of the capacitor 15. In the formulas for calculating the delay time td1 and the delay time td2, since the capacitance C [F] of the capacitor 15 is common, the delay time td1 and the delay time td2 can be adjusted by adjusting the resistance value R1 [Ω] of the first resistor 132 and the resistance value R2 [Ω] of the second resistor 142.

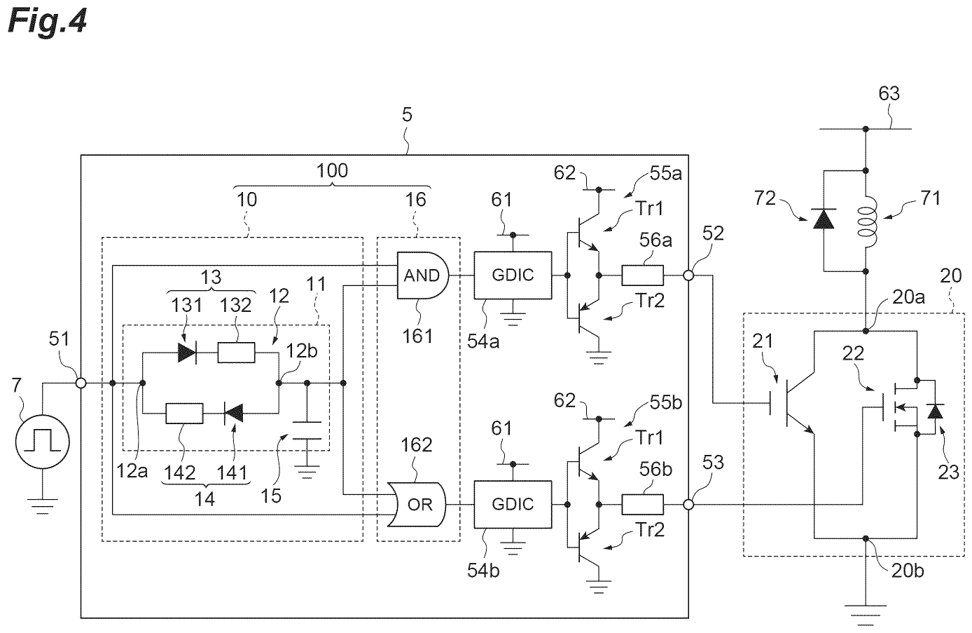

Next, Experimental Example 1 relating to the signal generation circuit 100 will be described. In Experimental Example 1, a double pulse test was conducted. FIG. 4 is a circuit diagram of a circuit used in the double pulse test in Experimental Example 1. As shown in FIG. 4, the double pulse test circuit used in Experimental Example 1 had the drive circuit 5 and the switch unit 20. The configurations of the drive circuit 5 and the switch unit 20 were the same as those of the drive circuit 5 and the switch unit 20 described using FIG. 2.

The resistance value of the first resistor 132 of the first series circuit 13 was 820 Ω.

The resistance value of the second resistor 142 of the second series circuit 14 was 820 Ω.

The capacitance of the capacitor 15 was 1 nF.

The same diode was used for the first diode and the second diode. The forward voltage of the first diode and the second diode was 0.6 V.

The first GDIC 54a and the second GDIC 54b were the same insulated gate driver ICs (BM6108FV-LB manufactured by ROHM Co., Ltd.).

The first power supply potential on the first power supply potential line 61 to which the first GDIC 54a and the second GDIC 54b are electrically connected was 5 V.

The second power supply potential on the second power supply potential line 62 to which the first push-pull circuit 55a and the second push-pull circuit 55b are electrically connected was 18 V.

The resistance values of the first gate resistor 56a and the second gate resistor 56b were 10 Ω.

In the AND circuit 161 and the OR circuit 162, the threshold voltages V_{IH} and V_{IL} described using FIG. 3 were 3 V and 2 V, respectively.

The first switching element 21 of the switch unit 20 was a Si-IGBT (MG7213 manufactured by ROHM Co., Ltd.), and the second switching element 22 was a SiC-MOSFET (S4603 manufactured by ROHM Co., Ltd.).

The node 20a of the switch unit 20 was connected to a power supply potential line 63 via a coil (inductive load) 71. The power supply potential supplied to the power supply potential line 63 was 600 V, and the series circuit of the coil 71 and the switch unit 20 was configured so that a current of 60 A flowed when the switch unit 20 was in the ON state. A freewheeling diode 72 was connected in antiparallel with the coil 71. That is, the cathode of the freewheeling diode 72 was connected to the end of the coil 71 on the power supply potential line 63 side, and the anode of the freewheeling diode 72 was connected to the end of the coil 71 on the node 20a side. The node 20b of the switch unit 20 was connected to ground.

In Experimental Example 1, a double pulse test was conducted using the double pulse test circuit shown in FIG. 4. Specifically, an input pulse signal was input from the external control device 7 serving as a pulse signal source to the drive circuit 5, the first switching element 21 was driven by the first gate signal output from the first output terminal 52, and the second switching element 22 was driven by the second gate signal output from the second output terminal 53. In the double pulse test, the gate voltage corresponding to each of the first gate signal and the second gate signal was measured, and the device current flowing through each of the first switching element 21 and the second switching element 22 was measured. Specifically, the gate-emitter voltage of the first switching element 21 was measured as the gate voltage corresponding to the first gate signal. The gate-source voltage of the second switching element 22 was measured as the gate voltage corresponding to the second gate signal. The collector current was measured as the device current flowing through the first switching element 21. The drain current flowing through the second switching element 22 was measured as the device current flowing through the second switching element 22.

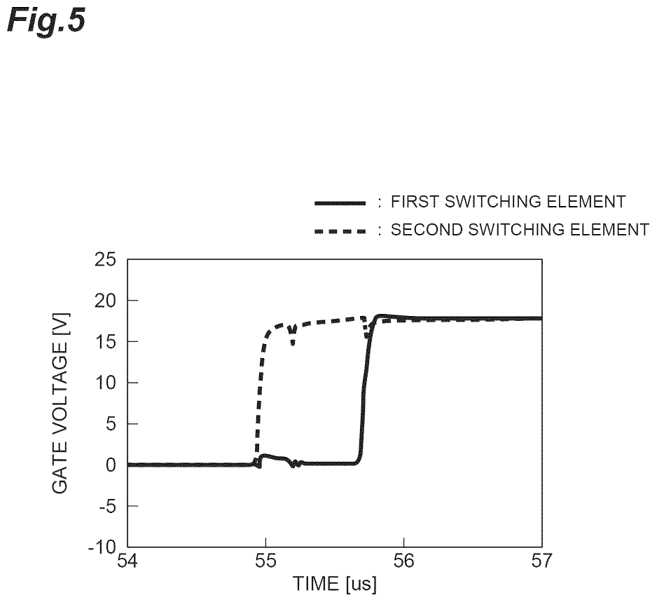

FIG. 5 is a graph showing measurement results of the gate voltage corresponding to the first gate signal and the gate voltage corresponding to the second gate signal at turn-on. The horizontal axis of FIG. 5 indicates time (μs), and the vertical axis indicates gate voltage (V). The solid line in FIG. 5 indicates the first gate voltage for driving the first switching element 21, and the dashed line in FIG. 5 indicates the second gate voltage for driving the second switching element 22.

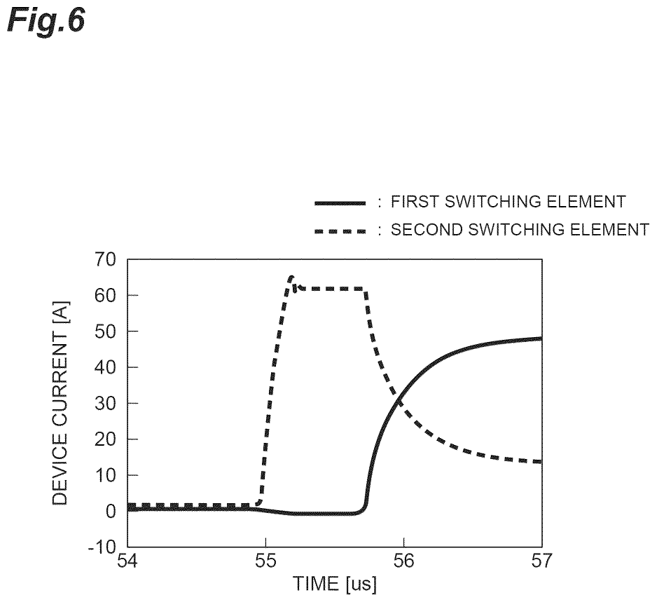

FIG. 6 is a graph showing measurement results of the device current flowing through the first switching element 21 and the device current flowing through the second switching element 22 at turn-on. The horizontal axis of FIG. 6 indicates time (μs), and the vertical axis indicates device current (A). The solid line in the figure indicates the device current flowing through the first switching element 21, and the dashed line in FIG. 6 indicates the device current flowing through the second switching element 22.

As can be understood from FIG. 5, the gate voltage of the second switching element 22 rose earlier than that of the first switching element 21. In response to this, as shown in FIG. 6, the second switching element 22 transitioned to the ON state before the first switching element 21. From FIG. 6, after the first switching element 21 turned on, the device current flowing through the first switching element 21 was greater than the device current flowing through the second switching element 22.

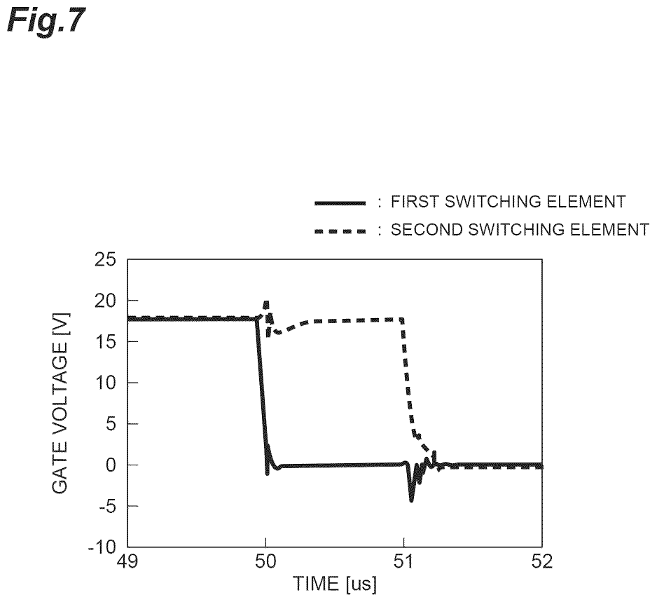

FIG. 7 is a graph showing measurement results of the gate voltage corresponding to the first gate signal and the gate voltage corresponding to the second gate signal at turn-off. The horizontal axis of FIG. 7 indicates time (μs), and the vertical axis indicates gate voltage (V). The solid line in FIG. 7 indicates the first gate voltage for driving the first switching element 21, and the dashed line in FIG. 7 indicates the second gate voltage for driving the second switching element 22.

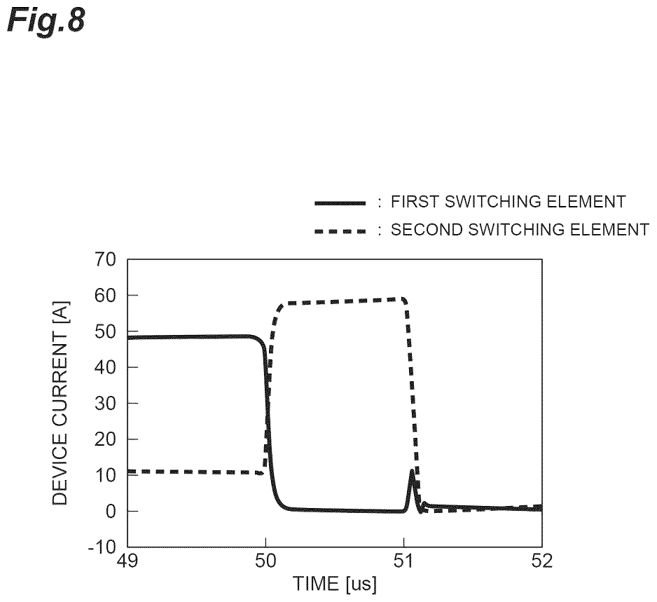

FIG. 8 is a graph showing measurement results of the device current flowing through the first switching element 21 and the device current flowing through the second switching element 22 at turn-off. The horizontal axis of FIG. 8 indicates time (μs), and the vertical axis indicates device current (A). The solid line in FIG. 8 indicates the device current flowing through the first switching element 21, and the dashed line in FIG. 8 indicates the device current flowing through the second switching element 22.

As can be understood from FIG. 7, the gate voltage of the first switching element 21 fell earlier than that of the second switching element 22. In response to this, as shown in FIG. 8, the first switching element 21 transitioned to the OFF state before the second switching element 22 did. In other words, the second switching element 22 transitioned to the OFF state later than the first switching element 21 did. From FIG. 8, until the first switching element 21 turned off, the device current flowing through the first switching element 21 was greater than the device current flowing through the second switching element 22.

From the results shown in FIG. 5 to FIG. 8, it is understood that the drive circuit 5 equipped with the signal generation circuit 100 can generate the first gate signal and the second gate signal for driving the first switching element 21 and the second switching element 22 from a common input pulse signal, and that the drive timings of the first switching element 21 and the second switching element 22 can be differentiated by the first gate signal and the second gate signal. Furthermore, it is understood that when both the first switching element 21 and the second switching element 22 are in the ON state, the first switching element 21 functions as the main current path in the switch unit 20.

### Second Embodiment

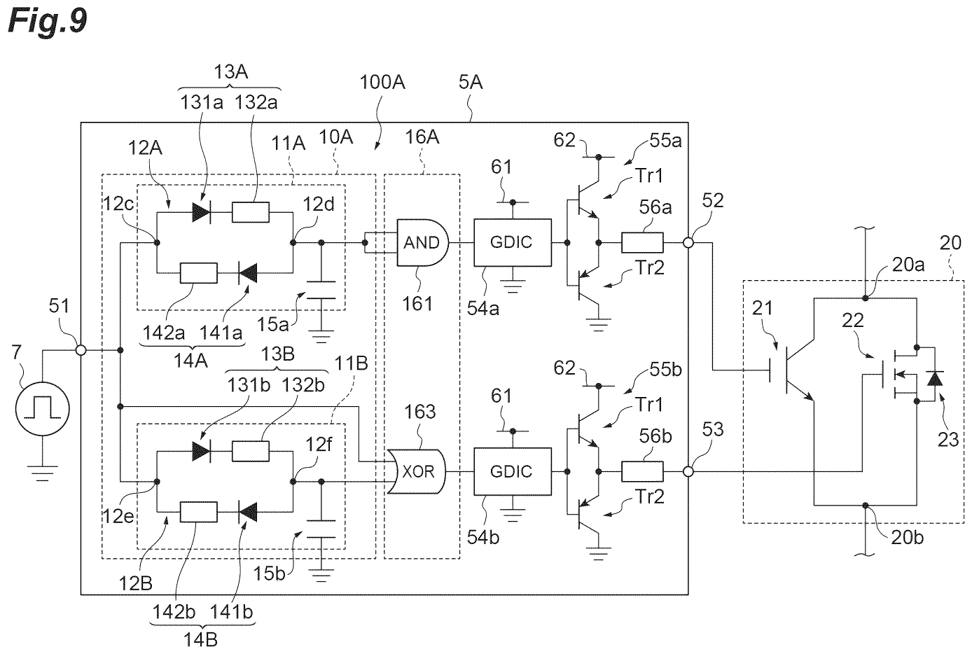

FIG. 9 is a circuit diagram of a drive circuit including a signal generation circuit according to the second embodiment. In FIG. 9, the switch unit 20 is also illustrated. The configuration of the switch unit 20 is the same as in the first embodiment. That is, the switch unit 20 is configured by connecting the first switching element 21 and the second switching element 22 in parallel. In the second embodiment as well, the first switching element 21 is a Si-IGBT, and the second switching element 22 is a SiC-MOSFET. Since the connection relationship between the first switching element 21 and the second switching element 22 is the same as in the first embodiment, the description thereof is omitted.

The drive circuit 5A according to the second embodiment differs from the drive circuit 5 mainly in that the drive circuit 5A has a signal generation circuit 100A instead of the signal generation circuit 100.

The drive circuit 5A has the signal generation circuit 100A, the first GDIC 54a, the first push-pull circuit 55a, the second GDIC 54b, the second push-pull circuit 55b, the first gate resistor 56a, and the second gate resistor 56b.

The signal generation circuit 100A has a delay signal generation unit 10A and a logic synthesis unit 16A. The delay signal generation unit 10A generates a first delayed pulse signal and a second delayed pulse signal having different delay states with respect to the input pulse signal. The logic synthesis unit 16A generates the first control pulse signal by performing a logical AND operation on a signal set of the first delayed pulse signals, and generates the second control pulse signal by performing an exclusive OR operation on a signal set of the second delayed pulse signal and the input pulse signal.

Since the configurations of the first GDIC 54a, the first push-pull circuit 55a, the second GDIC 54b, and the second push-pull circuit 55b are the same as in the first embodiment, the description thereof is omitted. The arrangement relationship of the first gate resistor 56a and the second gate resistor 56b is also the same as in the first embodiment. Therefore, in the drive circuit 5A, the circuit configuration for generating the first gate signal from the first control pulse signal generated by the signal generation circuit 100A and the circuit configuration for generating the second gate signal from the second control pulse signal generated by the signal generation circuit 100A are the same as in the first embodiment.

### [Signal Generation Circuit]

The delay signal generation unit 10A of the signal generation circuit 100A is configured to include a first delay circuit 11A and a second delay circuit 11B.

### First Delay Circuit

The first delay circuit 11A is configured to be capable of setting a resistance value for delaying the rising edge of the input pulse signal and a resistance value for delaying the falling edge of the input pulse signal. The first delay circuit 11A has a first parallel circuit (resistance unit) 12A in which a first series circuit 13A and a second series circuit 14A are connected in parallel, and a first capacitor 15a.

The first parallel circuit 12A has a node (first end) 12c and a node (second end) 12d. The node 12c is electrically connected to the input terminal 51. The input pulse signal is input to the node 12c from the external control device 7. The node 12d is electrically connected to the logic synthesis unit 16A.

The first series circuit 13A is configured by connecting a first diode 131a and a first resistor 132a in series. The anode of the first diode 131a is connected to the node 12c. The first resistor 132a is connected between the cathode of the first diode 131a and the node 12d. An example of the forward voltage of the first diode 131a and an example of the resistance value of the first resistor 132a are the same as those of the first diode 131 and the first resistor 132 described in the first embodiment.

The second series circuit 14A is configured by connecting a second diode 141a and a second resistor 142a in series. The anode of the second diode 141a is connected to the node 12d. The second resistor 142a is connected between the cathode of the second diode 141a and the node 12c. An example of the forward voltage of the second diode 141a and an example of the resistance value of the second resistor 142a are the same as those of the second diode 141 and the second resistor 142 described in the first embodiment.

The first capacitor 15a is electrically connected between the node 12d and ground. An example of the capacitance of the first capacitor 15a is the same as that of the capacitor 15 described in the first embodiment.

In the first delay circuit 11A, the first series circuit 13A functions as a signal path for delaying the rising edge of the input pulse signal, and the first series circuit 13A (specifically, the first resistor 132a) and the first capacitor 15a constitute a delay circuit that delays the rising edge of the input pulse signal. The delay time for the rising edge is determined by the resistance value of the first resistor 132a and the capacitance of the first capacitor 15a. That is, when the delay time for the rising edge imparted to the input pulse signal in the first delay circuit 11A is Td1_{ON} [s], the resistance value of the first resistor 132a is R1a [Ω], and the capacitance of the first capacitor 15a is C1 [F], Td1_{ON} is expressed by Formula (1).

$$Td {1}_{ON} = R 1 a \times C 1 \qquad ( 1 )$$

In the first delay circuit 11A, the second series circuit 14A functions as a signal path for delaying the falling edge of the input pulse signal, and the second series circuit 14A and the first capacitor 15a constitute a delay circuit that delays the falling edge of the input pulse signal. The delay time for the falling edge is determined by the resistance value of the second resistor 142a and the capacitance of the first capacitor 15a. That is, when the delay time for the falling edge imparted to the input pulse signal in the first delay circuit 11A is Td1_{OFF} [s] and the resistance value of the second resistor 142a is R2a [Ω], Td1_{OFF} is expressed by Formula (2).

$$Td {1}_{OFF} = R 2 a \times C 1 \qquad ( 2 )$$

### Second Delay Circuit

The second delay circuit 11B is configured such that a resistance value for delaying the rising edge of the input pulse signal and a resistance value for delaying the falling edge of the input pulse signal can be set. The second delay circuit 11B has a second parallel circuit (resistance unit) 12B in which a third series circuit 13B and a fourth series circuit 14B are connected in parallel, and a second capacitor 15b.

The second parallel circuit 12B has a node (third end) 12e and a node (fourth end) 12f. The node 12e is electrically connected to the input terminal 51. The input pulse signal is input to the node 12e from the external control device 7. The node 12f is electrically connected to the logic synthesis unit 16A.

The third series circuit 13B is configured by connecting a third diode 131b and a third resistor 132b in series. The anode of the third diode 131b is connected to the node 12e. The third resistor 132b is connected between the cathode of the third diode 131b and the node 12f. An example of the forward voltage of the third diode 131b and an example of the resistance value of the third resistor 132b are the same as those of the first diode 131 and the first resistor 132 described in the first embodiment. The third diode 131b may be the same as the first diode 131a, or may be different therefrom. The third resistor 132b may be the same as the first resistor 132a, or may be different therefrom.

The fourth series circuit 14B is configured by connecting a fourth diode 141b and a fourth resistor 142b in series. The anode of the fourth diode 141b is electrically connected to the node 12f. The fourth resistor 142b is electrically connected between the cathode of the fourth diode 141b and the node 12e. An example of the forward voltage of the fourth diode 141b and an example of the resistance value of the fourth resistor 142b are the same as those of the first diode 131 and the first resistor 132 described in the first embodiment. The fourth diode 141b may be the same as the second diode 141a or may be different. The fourth resistor 142b may be the same as the second resistor 142a or may be different.

The second capacitor 15b is electrically connected between the node 12f and ground. An example of the capacitance of the second capacitor 15b is the same as that of the capacitor 15 described in the first embodiment. The second capacitor 15b may be the same as the first capacitor 15a, or may be different.

In the second delay circuit 11B, the third series circuit 13B functions as a signal path for delaying the rising edge of the input pulse signal, and the third series circuit 13B (specifically, the third resistor 132b) and the second capacitor 15b constitute a delay circuit that delays the rising edge of the input pulse signal. The delay time for the rising edge is determined by the resistance value of the third resistor 132b and the capacitance of the second capacitor 15b. That is, when the delay time for the rising edge imparted to the input pulse signal in the second delay circuit 11B is Td2_{ON} [s], the resistance value of the third resistor 132b is R1b [Ω], and the capacitance of the second capacitor 15b is C2 [F], Td2_{ON} is expressed by formula (3).

$$Td {2}_{ON} = R 1 b \times C 2 \qquad ( 3 )$$

In the second delay circuit 11B, the fourth series circuit 14B functions as a signal path for delaying the falling edge of the input pulse signal, and the fourth series circuit 14B (specifically, the fourth resistor 142b) and the second capacitor 15b constitute a delay circuit that delays the falling edge of the input pulse signal. The delay time for the falling edge is determined by the resistance value of the fourth resistor 142b and the capacitance of the second capacitor 15b. That is, when the delay time for the falling edge imparted to the input pulse signal in the second delay circuit 11B is Td2_{OFF} [s] and the resistance value of the fourth resistor 142b is R2b [Ω], Td2_{OFF} is expressed by formula (4).

$$Td {2}_{OFF} = R 2 b \times C 2 \qquad ( 4 )$$

In the second embodiment, the delay times Td1_{ON}, Td1_{OFF}, Td2_{ON}, and Td2_{OFF} defined by formulas (1), (2), (3), and (4) satisfy the relationships of formula (5) and formula (6).

$$Td {1}_{ON} < Td {2}_{ON} \qquad ( 5 )$$

$$Td {1}_{OFF} < Td {2}_{OFF} \qquad ( 6 )$$

In other words, the resistance value R1a of the first resistor 132a, the resistance value R2a of the second resistor 142a, the capacitance C1 of the first capacitor 15a, the resistance value R1b of the third resistor 132b, the resistance value R2b of the fourth resistor 142b, and the capacitance C2 of the second capacitor 15b are set so as to satisfy formula (5) and formula (6).

### Logic Synthesis Unit

The logic synthesis unit 16A is configured to include an AND circuit 161 for generating the first control pulse signal and an XOR circuit 163 for generating the second control pulse signal.

The AND circuit 161 is electrically connected to the first delay circuit 11A. A signal set of the first delayed pulse signals is input to the AND circuit 161. That is, a pair of first delayed pulse signals is input to the AND circuit 161 from the delay signal generation unit 10A. The AND circuit 161 is a logical product circuit that outputs the first control pulse signal by performing a logical AND operation on the first delayed pulse signals that have been input. The AND circuit 161 is electrically connected to the first GDIC 54a, and the first control pulse signal output from the AND circuit 161 is input to the first GDIC 54a.

The XOR circuit 163 is electrically connected to the input terminal 51 and the second delay circuit 11B. A signal set of the input pulse signal and the second delayed pulse signal is input to the XOR circuit 163. The XOR circuit 163 is an exclusive OR circuit that outputs the second control pulse signal by performing an exclusive OR operation on the input pulse signal and the second delayed pulse signal that has been input. The XOR circuit 163 is electrically connected to the second GDIC 54b, and the second control pulse signal output from the XOR circuit 163 is input to the second GDIC 54b.

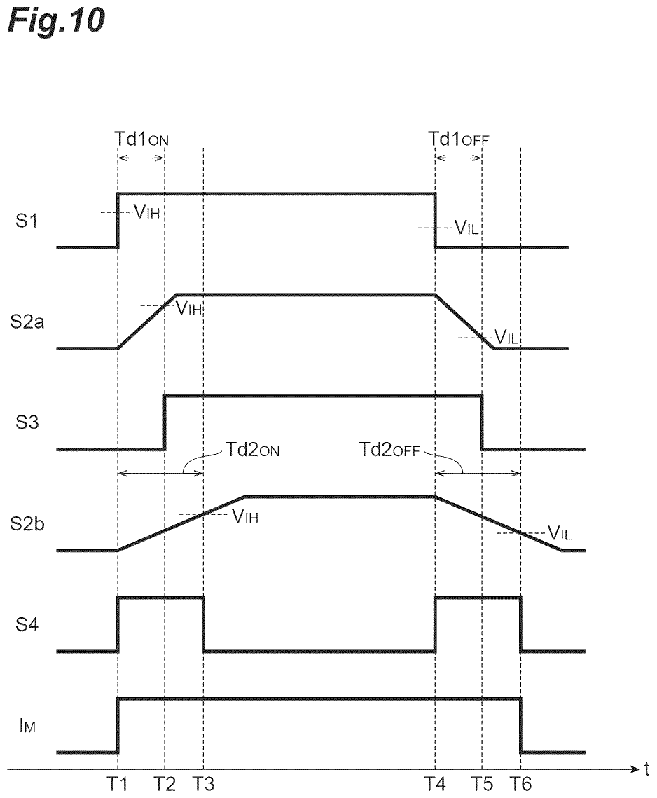

FIG. 10 is a time chart of various signals in the second embodiment. In FIG. 10, the input pulse signal, the first delayed pulse signal, the second delayed pulse signal, the first control pulse signal, the second control pulse signal, and the main circuit current are represented as input pulse signal S1, first delayed pulse signal S2a, second delayed pulse signal S2b, first control pulse signal S3, second control pulse signal S4, and main circuit current I_{M}, respectively. As in the first embodiment, the main circuit current I_{M} is the current flowing through the switch unit 20.

In FIG. 10, the threshold voltage (threshold signal level) for regarding an input signal as High and the threshold voltage (threshold signal level) for regarding the input signal as Low in the AND circuit 161 and the XOR circuit 163 are shown as V_{IH} and V_{IL}, respectively. In the AND circuit 161 and the XOR circuit 163, once the input signal exceeds V_{IH}, it is regarded as a High state unless it falls below V_{IL}, and once the input signal falls below V_{IL}, it is regarded as a Low state unless it exceeds V_{IH} again. An example of V_{IH} is 3 V, and an example of V_{IL} is 2 V.

The operation of the drive circuit 5A and the switch unit 20 will be described with reference to FIG. 9 and FIG. 10.

As shown in FIG. 10, the input pulse signal S1 has a pulse that rises at time T1 and falls at time T4. When the input pulse signal S1 is input to the delay signal generation unit 10A, the delay signal generation unit 10A generates the first delayed pulse signal S2a and the second delayed pulse signal S2b.

The first delay circuit 11A included in the delay signal generation unit 10A has the first parallel circuit 12A and the first capacitor 15a. The first parallel circuit 12A has the first series circuit 13A that contributes to the delay of the rising edge and the second series circuit 14A that contributes to the delay of the falling edge. Therefore, as shown in FIG. 10, the first delayed pulse signal S2a rises at time T2, which is after a delay time Td1_{ON} from time T1, and falls at time T5, which is after a delay time Td1_{OFF} from time T4. The meanings of “rising after a delay time from time α” and “falling after a delay time from time β” are the same as in the first embodiment. In the example shown in FIG. 10 as well, the threshold level that determines the delay time for the rising edge is V_{IH}, which is the same as the threshold voltage for regarding a signal input to the AND circuit 161 and the XOR circuit 163 as High, and the threshold level that determines the delay time for the falling edge is V_{IL}, which is the same as the threshold voltage for regarding a signal input to the AND circuit 161 and the XOR circuit 163 as Low.

The first delayed pulse signal S2a generated by the first delay circuit 11A is input to the logic synthesis unit 16A. Specifically, a pair of first delayed pulse signals S2a is input to the AND circuit 161. The AND circuit 161 performs a logical AND operation on the signal set of the first delayed pulse signals S2a to generate the first control pulse signal S3.

In the example shown in FIG. 10, the signal level (voltage) of the first delayed pulse signal S2a exceeds the threshold voltage V_{IH} at time T2 and falls below the threshold voltage V_{IL} at time T5. Therefore, the first delayed pulse signal S2a input to the AND circuit 161 is processed as a signal that is in a High state from time T2 to time T5 in the AND circuit 161 and thereafter maintains a Low state until it exceeds the threshold voltage V_{IH} again.

The first control pulse signal S3 is generated by the logical AND of the first delayed pulse signals S2a. From the relationship between the above-described High and Low states of the first delayed pulse signal S2a in the AND circuit 161, the first control pulse signal S3 is a pulse signal that rises at time T2 and falls at time T5.

The second delay circuit 11B included in the delay signal generation unit 10A has the second parallel circuit 12B and the second capacitor 15b. The second parallel circuit 12B has the third series circuit 13B that contributes to the delay of the rising edge and the fourth series circuit 14B that contributes to the delay of the falling edge. Furthermore, in the present embodiment, the resistance value R1a of the first resistor 132a, the resistance value R2a of the second resistor 142a, the capacitance C1 of the first capacitor 15a, the resistance value R1b of the third resistor 132b, the resistance value R2b of the fourth resistor 142b, and the capacitance C2 of the second capacitor 15b are set so as to satisfy Formulas (5) and (6).

Therefore, as shown in FIG. 10, the second delayed pulse signal S2b rises at time T3, which is after a delay time Td2_{ON} from time T1, and falls at time T6, which is after a delay time Td2_{OFF} from time T4. The meanings of “rising after a delay time from time α” and “falling after a delay time from time β” are the same as in the first embodiment. In the example shown in FIG. 10 as well, the threshold level that determines the delay time for the rising edge is V_{IH}, which is the same as the threshold voltage for regarding a signal input to the AND circuit 161 and the XOR circuit 163 as High, and the threshold level that determines the delay time for the falling edge is V_{IL}, which is the same as the threshold voltage for regarding a signal input to the AND circuit 161 and the XOR circuit 163 as Low.

The second delayed pulse signal S2b generated by the second delay circuit 11B is input to the logic synthesis unit 16A. Specifically, the second delayed pulse signal S2b is input to the XOR circuit 163. The input pulse signal S1 is also input to the XOR circuit 163. The XOR circuit 163 performs an exclusive OR operation on the signal set of the input pulse signal S1 and the second delayed pulse signal S2b to generate the second control pulse signal S4.

In the example shown in FIG. 10, the signal level (voltage) of the input pulse signal S1 exceeds the threshold voltage V_{IH} at time T1 and falls below the threshold voltage V_{IL} at time T4. Therefore, the input pulse signal S1 input to the XOR circuit 163 is processed as a signal that is in a High state from time T1 to time T4 in the XOR circuit 163 and thereafter maintains a Low state until it exceeds the threshold voltage V_{IH} again.

The signal level (voltage) of the second delayed pulse signal S2b exceeds the threshold voltage V_{IH} at time T3 and falls below the threshold voltage V_{IL} at time T6. Therefore, the second delayed pulse signal S2b input to the XOR circuit 163 is processed as a signal that is in a High state from time T3 to time T6 in the XOR circuit 163 and thereafter maintains a Low state until it exceeds the threshold voltage V_{IH} again.

The second control pulse signal S4 is generated by an exclusive OR operation on the signal set of the input pulse signal S1 and the second delayed pulse signal S2b. From the relationship between the above-described High and Low states of the input pulse signal S1 and the second delayed pulse signal S2b in the XOR circuit 163, the second control pulse signal S4 is a pulse signal that rises at time T1, then falls at time T3, and rises again at time T4, then falls at time T6.

In this way, the signal generation circuit 100A can generate the first control pulse signal S3 and the second control pulse signal S4 that are different from each other, based on the same input pulse signal.

In the drive circuit 5A, the first control pulse signal S3 is input to the first GDIC 54a and output as the first output pulse signal. The first output pulse signal output from the first GDIC 54a is input to the first push-pull circuit 55a and output as the first gate signal. The first gate signal is input to the first output terminal 52 via the first gate resistor 56a. Since the first output terminal 52 is electrically connected to the gate of the first switching element 21, the first switching element 21 is driven by the first gate signal.

Since the first output pulse signal is a pulse signal obtained by amplifying the first control pulse signal, the first output pulse signal has the same waveform as the first control pulse signal. Since the first gate signal is a pulse signal obtained by amplifying the first output pulse signal, the first gate signal has the same waveform as the first output pulse signal. Therefore, the first gate signal has the same waveform as the first control pulse signal S3.

In the drive circuit 5A, the second control pulse signal S4 is input to the second GDIC 54b and output as the second output pulse signal. The second output pulse signal output from the second GDIC 54b is input to the second push-pull circuit 55b and output as the second gate signal. The second gate signal is input to the second output terminal 53 via the second gate resistor 56b. Since the second output terminal 53 is electrically connected to the gate of the second switching element 22, the second switching element 22 is driven by the second gate signal.

Since the second output pulse signal is a pulse signal obtained by amplifying the second control pulse signal, the second output pulse signal has the same waveform as the second control pulse signal. Since the second gate signal is a pulse signal obtained by amplifying the second output pulse signal, the second gate signal has the same waveform as the second output pulse signal. Therefore, the second gate signal has the same waveform as the second control pulse signal S4.

Since the first switching element 21 is driven by the first gate signal having the same waveform as the first control pulse signal S3, it turns on at time T2 and turns off at time T5. Since the second switching element 22 is driven by the second gate signal having the same waveform as the second control pulse signal S4, it turns on at time T1, turns off once at time T3, turns on again at time T4, and then turns off at time T6. Therefore, the second switching element 22 is in the ON state from time T1 to time T3, in the OFF state from time T3 to time T4, and in the ON state from time T4 to time T6. Of the two ON states of the second switching element 22, the ON state from time T1 to time T3 is referred to as the first ON state, and the ON state from time T4 to time T6, which is after the first ON state, is referred to as the second ON state.

As described above, since the first switching element 21 turns on at time T2, the first switching element 21 turns on during the period from time T1 to time T3 (while the second switching element 22 is in the first ON state). Such a relationship is realized by the delay time Td1_{ON} and the delay time Td2_{ON} satisfying formula (5).

As described above, since the first switching element 21 turns off at time T5, the first switching element 21 turns off during the period from time T4 to time T5 (while the second switching element 22 is in the second ON state). Such a relationship is realized by the delay time Td1_{OFF} and the delay time Td2_{OFF} satisfying formula (6).

The switch unit 20 is configured by connecting the first switching element 21 and the second switching element 22 in parallel. Therefore, as in the first embodiment, when either one of the first switching element 21 and the second switching element 22 is in the ON state, the switch unit 20 is in the ON state, and when both the first switching element 21 and the second switching element 22 are in the OFF state, the switch unit 20 is in the OFF state. Therefore, the switch unit 20 is in the ON state from time T1 to time T6, and as shown in FIG. 10, the main circuit current I_{M} flows from time T1 to time T6.

As can be understood from the time chart of various signals shown in FIG. 10, in the configuration of the drive circuit 5A having the signal generation circuit 100A, the second switching element 22, which is a SiC-MOSFET, is in the ON state from time T1 to time T3, in the OFF state from time T3 to time T4, and in the ON state from time T4 to time T6. On the other hand, in the configuration of the drive circuit 5A having the signal generation circuit 100A, the first switching element 21, which is a Si-IGBT, is in the ON state from time T2 to time T5. Therefore, in the present embodiment, the second switching element 22 is responsible substantially only for the turn-on and turn-off functions of the switch unit 20, and the first switching element 21 functions as the substantial current path when the switch unit 20 is in the ON state.

The Si-IGBT has smaller conduction loss at a large current than the SiC-MOSFET and is resistant to overcurrent. Therefore, since the current path when the switch unit 20 is in the ON state is the first switching element 21 (Si-IGBT), the resistance of the switch unit 20 to overcurrent is improved. Since the second switching element 22 (SiC-MOSFET) is responsible for the turn-on and turn-off functions of the switch unit 20, the switch unit 20 is capable of high-speed switching.

The signal generation circuit 100A can generate a first control pulse signal and a second control pulse signal that are different from each other from a common input pulse signal for the first switching element 21 and the second switching element 22. As described above, the drive circuit 5A can output the first gate signal for driving the first switching element 21 and the second gate signal for driving the second switching element 22 in response to the first control pulse signal and the second control pulse signal. Therefore, the signal generation circuit 100A and the drive circuit 5A have the same advantageous effects as in the first embodiment.

The combination of the drive circuit 5A and the switch unit 20 can be applied to the power conversion device 1 shown in FIG. 1 instead of the combination of the drive circuit 5 and the switch unit 20. Since the drive circuit 5A has the same advantageous effects as in the first embodiment, the power conversion device 1 to which the combination of the drive circuit 5A and the switch unit 20 is applied also has the same advantageous effects as in the first embodiment.

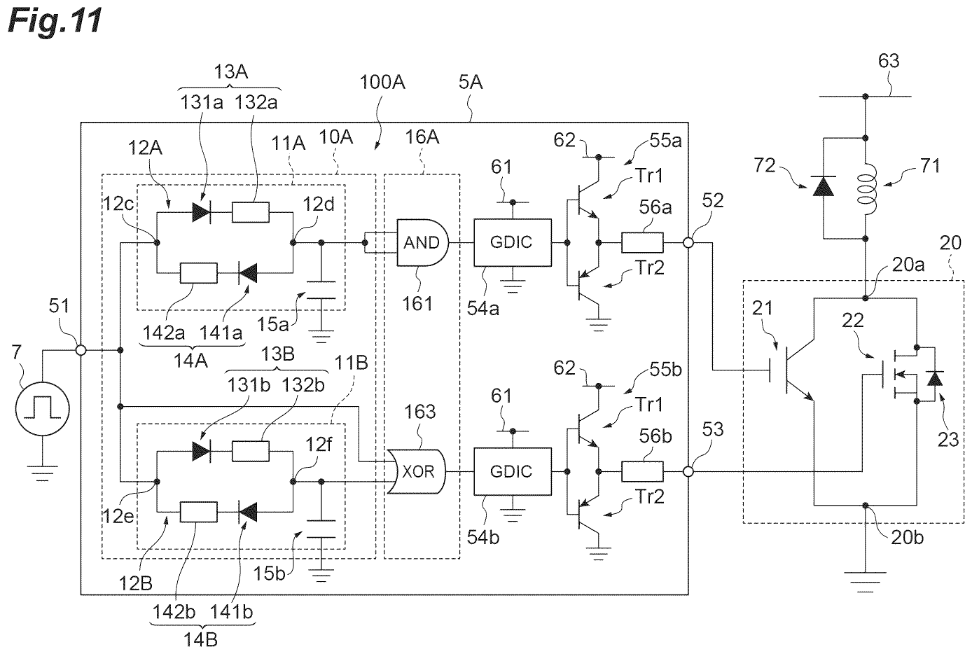

Next, Experimental Example 2 relating to the signal generation circuit 100A will be described. In Experimental Example 2, a double pulse test was conducted. FIG. 11 is a circuit diagram of a circuit used in the double pulse test in Experimental Example 2. As shown in FIG. 11, the double pulse test circuit used in Experimental Example 2 had the drive circuit 5A and the switch unit 20. The configurations of the drive circuit 5A and the switch unit 20 were the same as those of the drive circuit 5A and the switch unit 20 described using FIG. 9.

The resistance value of the first resistor 132a of the first series circuit 13A was 560 Ω.

The resistance value of the second resistor 142a of the second series circuit 14A was 820 Ω.

The capacitance of the first capacitor 15a was 1 nF.

The resistance value of the third resistor 132b of the third series circuit 13B was 560 Ω.

The resistance value of the fourth resistor 142b of the fourth series circuit 14B was 820 Ω.

The capacitance of the second capacitor 15b was 1 nF.

The same diodes as the first diode 131 and the second diode 141 in Experimental Example 1 were used for the first diode 131a, the second diode 141a, the third diode 131b, and the fourth diode 141b.

The same GDICs as in Experimental Example 1 were used for the first GDIC 54a and the second GDIC 54b.

The first power supply potential on the first power supply potential line 61 to which the first GDIC 54a and the second GDIC 54b are electrically connected was 5 V.

The second power supply potential on the second power supply potential line 62 to which the first push-pull circuit 55a and the second push-pull circuit 55b are electrically connected was 18 V.

The same gate resistor as the first gate resistor 56a in Experimental Example 1 was used for the first gate resistor 56a.

The same gate resistor as the second gate resistor 56b in Experimental Example 1 was used for the second gate resistor 56b.

In the AND circuit 161 and the XOR circuit 163, the threshold voltages V_{IH} and V_{IL} described using FIG. 10 were 3 V and 2 V, respectively.

The first switching element 21 of the switch unit 20 was a Si-IGBT (MG7213 manufactured by ROHM Co., Ltd.), and the second switching element 22 was a SiC-MOSFET (S4603 manufactured by ROHM Co., Ltd.).

The node 20a of the switch unit 20 was electrically connected to a power supply potential line 63 via a coil (inductive load) 71. The power supply potential supplied to the power supply potential line 63 was 600 V, and the series circuit of the coil 71 and the switch unit 20 was configured so that a current of 60 A flowed when the switch unit 20 was in the ON state. As in Experimental Example 1, a freewheeling diode 72 was connected in antiparallel with the coil 71. The node 20b of the switch unit 20 was connected to ground.

In Experimental Example 2, a double pulse test was conducted using the double pulse test circuit shown in FIG. 11. Specifically, an input pulse signal was input from the external control device 7 serving as a pulse signal source to the drive circuit 5A, the first switching element 21 was driven by the first gate signal output from the first output terminal 52, and the second switching element 22 was driven by the second gate signal output from the second output terminal 53. In the double pulse test, the gate voltage corresponding to each of the first gate signal and the second gate signal was measured, and the device current flowing through each of the first switching element 21 and the second switching element 22 was measured in the same manner as in Experimental Example 1.

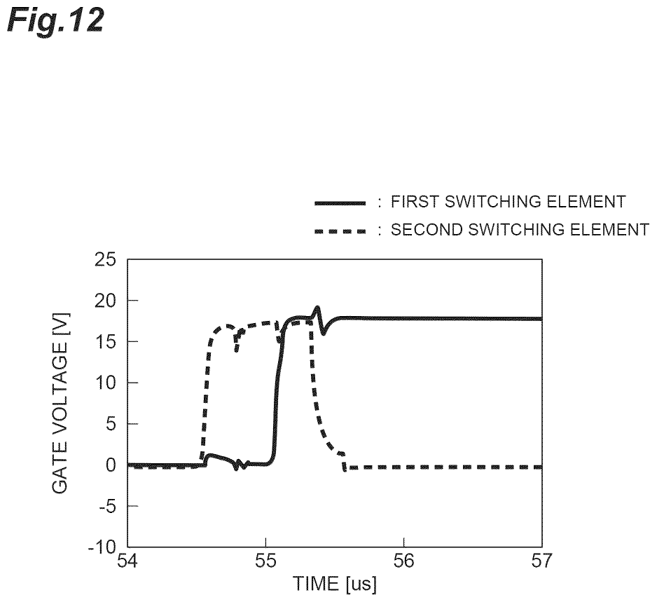

FIG. 12 is a graph showing measurement results of the gate voltage corresponding to the first gate signal and the gate voltage corresponding to the second gate signal at turn-on. The horizontal axis of FIG. 12 indicates time (μs), and the vertical axis indicates gate voltage (V). The solid line in FIG. 12 indicates the first gate voltage for driving the first switching element 21, and the dashed line in FIG. 12 indicates the second gate voltage for driving the second switching element 22.

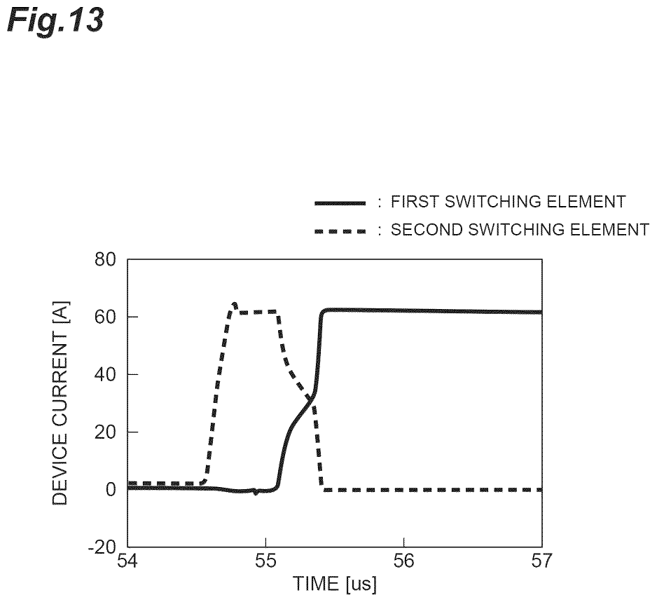

FIG. 13 is a graph showing measurement results of the device current flowing through the first switching element 21 and the device current flowing through the second switching element 22 at turn-on. The horizontal axis of FIG. 13 indicates time (μs), and the vertical axis indicates device current (A). The solid line in the figure indicates the device current flowing through the first switching element 21, and the dashed line in FIG. 13 indicates the device current flowing through the second switching element 22.

As can be understood from FIG. 12, the gate voltage of the second switching element 22 rose earlier than that of the first switching element 21, and the gate voltage of the second switching element 22 fell after the gate voltage of the first switching element 21 rose. In response to this, as shown in FIG. 13, the second switching element 22 transitioned to the ON state before the first switching element 21, and after the first switching element 21 entered the ON state, the second switching element 22 transitioned to the OFF state.

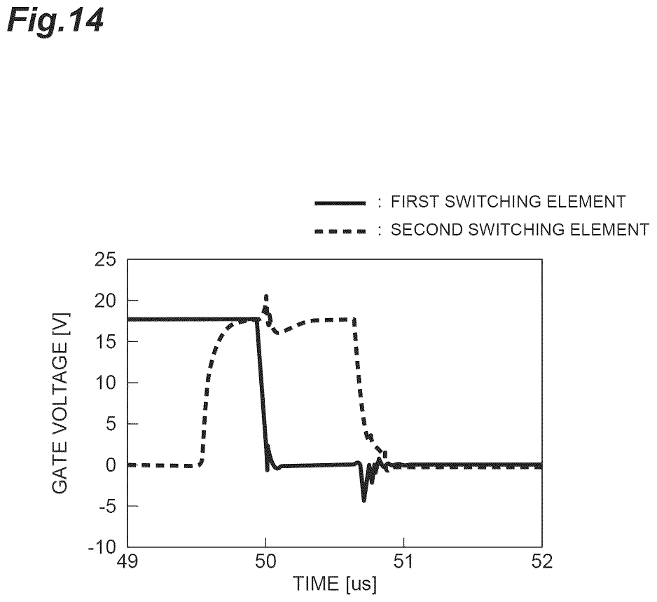

FIG. 14 is a graph showing measurement results of the gate voltage corresponding to the first gate signal and the gate voltage corresponding to the second gate signal at turn-off. The horizontal axis of FIG. 14 indicates time (μs), and the vertical axis indicates gate voltage (V). The solid line in FIG. 14 indicates the first gate voltage for driving the first switching element 21, and the dashed line in FIG. 14 indicates the second gate voltage for driving the second switching element.

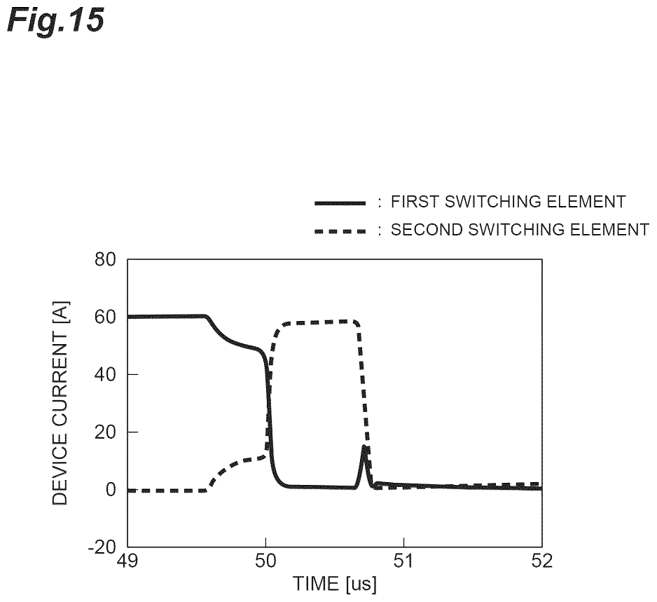

FIG. 15 is a graph showing measurement results of the device current flowing through the first switching element 21 and the device current flowing through the second switching element 22 at turn-off. The horizontal axis of FIG. 15 indicates time (μs), and the vertical axis indicates device current (A). The solid line in FIG. 15 indicates the device current flowing through the first switching element 21, and the dashed line in FIG. 15 indicates the device current flowing through the second switching element 22.

As can be understood from FIG. 14, before the gate voltage of the first switching element 21 fell, the gate voltage of the second switching element 22 was 0 V. Shortly before the gate voltage of the first switching element 21 fell, the second switching element 22 rose, and after the gate voltage of the first switching element 21 fell, the second switching element 22 fell. In response to this, as shown in FIG. 15, before the first switching element 21 transitioned to the OFF state, the second switching element 22 was in the OFF state. Shortly before the first switching element 21 transitioned to the OFF state, the second switching element 22 transitioned to the ON state, and after the first switching element 21 transitioned to the OFF state, the second switching element 22 transitioned to the OFF state.

From the results shown in FIG. 13 to FIG. 15, it can be understood that in the drive circuit 5A equipped with the signal generation circuit 100A, the first gate signal and the second gate signal for driving the first switching element 21 and the second switching element 22 can be generated from a common input pulse signal such that the second switching element 22 is responsible only for the turn-on and turn-off functions in the switch unit 20, and the first switching element 21 is responsible for the current path when the switch unit 20 is in the ON state.

### Third Embodiment

In the first embodiment and the second embodiment, the number of first switching elements and the number of second switching elements included in the switch unit were each one. However, the number of first switching elements is not limited to one, and the number of second switching elements is also not limited to one.

In the third embodiment, a case where the switch unit includes one first switching element 21 and two second switching elements will be described.

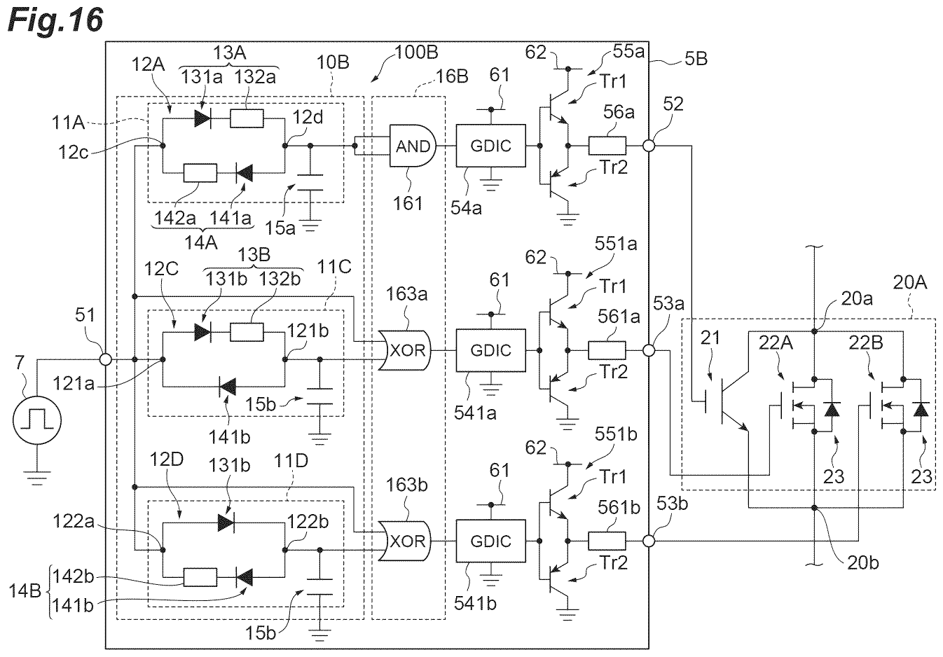

FIG. 16 is a circuit diagram of a drive circuit 5B including a signal generation circuit 100B according to the third embodiment. The drive circuit 5B is a circuit for driving the switch unit 20A shown in FIG. 16.

The switch unit 20A has the first switching element 21, a second-a switching element 22A, and a second-b switching element 22B. In the third embodiment as well, the first switching element 21 is a Si-IGBT, and the second-a switching element 22A and the second-b switching element 22B are SiC-MOSFETs. A freewheeling diode 23 may be connected in antiparallel with each of the second-a switching element 22A and the second-b switching element 22B.

The first switching element 21, the second-a switching element 22A, and the second-b switching element 22B are connected in parallel between the node 20a and the node 20b. Specifically, the collector of the first switching element 21, the drain of the second-a switching element 22A, and the drain of the second-b switching element 22B are electrically connected to the node 20a, and the emitter of the first switching element 21, the source of the second-a switching element 22A, and the source of the second-b switching element 22B are electrically connected to the node 20b.

The switch unit 20A is applied to the power conversion device 1 shown in FIG. 1 instead of the switch unit 20.

The drive circuit 5B differs from the drive circuit 5 mainly in that the drive circuit 5B has a signal generation circuit 100B instead of the signal generation circuit 100. That is, the drive circuit 5B has the signal generation circuit 100B, the first GDIC 54a, the first push-pull circuit 55a, a second-a GDIC (second-a driver) 541a, a second-a push-pull circuit 551a, a second-b GDIC (second-b driver) 541b, a second-b push-pull circuit 551b, the first gate resistor 56a, a second-a gate resistor 561a, and a second-b gate resistor 561b.

The signal generation circuit 100B has a delay signal generation unit 10B and a logic synthesis unit 16B.

The delay signal generation unit 10B generates a first delayed pulse signal, a second-a delayed pulse signal, and a second-b delayed pulse signal having different delay states with respect to the input pulse signal. The second-a delayed pulse signal is a pulse signal that is delayed with respect to the rising edge of the input pulse signal, and the second-b delayed pulse signal is a pulse signal that is delayed with respect to the falling edge of the input pulse signal.

The logic synthesis unit 16B generates the first control pulse signal by performing a logical AND operation on a signal set of the first delayed pulse signals. The logic synthesis unit 16B generates the second-a control pulse signal by performing an exclusive OR operation on a signal set of the input pulse signal and the second-a delayed pulse signal. The logic synthesis unit 16B generates the second-b control pulse signal by performing an exclusive OR operation on a signal set of the input pulse signal and the second-b delayed pulse signal.

Since the configurations of the first GDIC 54a and the first push-pull circuit 55a are the same as in the first embodiment, the description thereof is omitted. The arrangement relationship of the first push-pull circuit 55a and the first gate resistor 56a is also the same as in the first embodiment.

The second-a GDIC 541a is connected between the first power supply potential line 61 and ground. The second-a GDIC 541a outputs a second-a output pulse signal based on the second-a control pulse signal. The second-a output pulse signal is a signal obtained by amplifying the second-a control pulse signal. In the present embodiment, the second-a output pulse signal is a signal that drives the second-a push-pull circuit 551a.

The second-a GDIC 541a has a function of transmitting a signal while isolating the signal generation circuit 100B from the second-a push-pull circuit 551a, and a function of amplifying the second-a control pulse signal. For example, a configuration example of the second-a GDIC 541a is the same as that of the first GDIC 54a.

The second-a push-pull circuit 551a has a first transistor Tr1 and a second transistor Tr2 connected in series between the second power supply potential line 62 and ground. The second-a push-pull circuit 551a is a totem-pole output stage in which the first transistor Tr1 and the second transistor Tr2 are connected in series. The first transistor Tr1 and the second transistor Tr2 are an npn transistor and a pnp transistor, respectively.

The electrical connection relationship among the first transistor Tr1 and the second transistor Tr2 of the second-a push-pull circuit 551a, the second power supply potential line 62, and ground is the same as that of the first push-pull circuit 55a. The gates of each of the first transistor Tr1 and the second transistor Tr2 of the second-a push-pull circuit 551a are electrically connected to the second-a GDIC 541a, and the second-a output pulse signal is input from the second-a GDIC 541a.

The node between the emitter of the first transistor Tr1 and the emitter of the second transistor Tr2 is electrically connected to a second-a output terminal 53a via the second-a gate resistor 561a. An example of the resistance value of the second-a gate resistor 561a is the same as that of the first gate resistor 56a.

In the second-a push-pull circuit 551a having the above configuration, the first transistor Tr1 and the second transistor Tr2 are driven in response to the second-a output pulse signal from the second-a GDIC 541a. As a result, a second-a gate signal (second-a drive pulse signal) obtained by amplifying the second-a output pulse signal is obtained. The second-a gate signal is input to the second-a output terminal 53a via the second-a gate resistor 561a. Since the second-a output terminal 53a is electrically connected to the gate of the second-a switching element 22A, the second-a gate signal is input to the gate of the second-a switching element 22A.

The second-b GDIC 541b is connected between the first power supply potential line 61 and ground. The second-b GDIC 541b outputs a second-b output pulse signal based on the second-b control pulse signal. The second-b output pulse signal is a signal obtained by amplifying the second-b control pulse signal. In the present embodiment, the second-b output pulse signal is a signal that drives the second-b push-pull circuit 551b.

The second-b GDIC 541b has a function of transmitting a signal while isolating the signal generation circuit 100B from the second-b push-pull circuit 551b, and a function of amplifying the second-b control pulse signal. For example, the configuration example of the second-b GDIC 541b is the same as that of the first GDIC 54a.

The second-b push-pull circuit 551b has a first transistor Tr1 and a second transistor Tr2 connected in series between the second power supply potential line 62 and ground. The second-b push-pull circuit 551b is a totem-pole output stage in which the first transistor Tr1 and the second transistor Tr2 are connected in series. The first transistor Tr1 and the second transistor Tr2 are an npn transistor and a pnp transistor, respectively.

The electrical connection relationship among the first transistor Tr1 and the second transistor Tr2 of the second-b push-pull circuit 551b, the second power supply potential line 62, and ground is the same as that of the first push-pull circuit 55a. The gates of each of the first transistor Tr1 and the second transistor Tr2 of the second-b push-pull circuit 551b are electrically connected to the second-b GDIC 541b, and the second-b output pulse signal is input from the second-b GDIC 541b.

The node between the emitter of the first transistor Tr1 and the emitter of the second transistor Tr2 is electrically connected to a second-b output terminal 53b via the second-b gate resistor 561b. An example of the resistance value of the second-b gate resistor 561b is the same as that of the second gate resistor 56b.

In the second-b push-pull circuit 551b having the above configuration, the first transistor Tr1 and the second transistor Tr2 are driven in response to the second-b output pulse signal from the second-b GDIC 541b. As a result, a second-b gate signal (second-b drive pulse signal) obtained by amplifying the second-b output pulse signal is obtained. The second-b gate signal is input to the second-b output terminal 53b via the second-b gate resistor 561b. Since the second-b output terminal 53b is electrically connected to the gate of the second-b switching element 22B, the second-b gate signal is input to the gate of the second-b switching element 22B.

### [Signal Generation Circuit]

The delay signal generation unit 10B of the signal generation circuit 100B is configured to include the first delay circuit 11A, a second-a delay circuit 11C, and a second-b delay circuit 11D.

Since the configuration of the first delay circuit 11A is the same as that of the first delay circuit 11A in the second embodiment, the description thereof is omitted.

The second-a delay circuit 11C has a second-a parallel circuit 12C, in which a third series circuit (third-a series circuit) 13B and a fourth diode (third-b diode) 141b are connected in parallel, and a second capacitor (second-a capacitor) 15b.

The second-a parallel circuit 12C has a node (third-a end) 121a and a node (third-b end) 121b. The node 121a is electrically connected to the input terminal 51. The input pulse signal is input to the node 121a from the external control device 7. The node 121b is electrically connected to the logic synthesis unit 16B.

The third series circuit 13B has the same configuration as the third series circuit 13B described in the second embodiment. That is, the third series circuit 13B is configured by connecting a third diode (third-a diode) 131b and a third resistor (third-a resistor) 132b in series. The anode of the third diode 131b is connected to the node 121a. The third resistor 132b is connected between the cathode of the third diode 131b and the node 121b.

The anode of the fourth diode 141b is connected to the node 121b, and the cathode of the fourth diode 141b is connected to the node 121a.

The second capacitor 15b is electrically connected between the node 121b and ground.

In the second-a delay circuit 11C, the third series circuit 13B functions as a signal path for delaying the rising edge of the input pulse signal, as described in the second embodiment, and the third series circuit 13B (specifically, the third resistor 132b) and the second capacitor 15b constitute a delay circuit that delays the rising edge of the input pulse signal. In the second-a parallel circuit 12C, only the fourth diode 141b is connected in parallel with the third series circuit 13B as described above, instead of the fourth series circuit 14B. Therefore, the second-a delay circuit 11C does not have the function of delaying the falling edge of the input pulse signal.

Therefore, the second-a delay circuit 11C is a circuit corresponding to the function of delaying the rising edge of the input pulse signal among the functions of the second delay circuit 11B in the second embodiment. The delay time Td2_{ON} occurring at the rising edge of the input pulse signal by the second-a delay circuit 11C is defined by formula (3) described in the second embodiment.

The second-b delay circuit 11D has a second-b parallel circuit 12D, in which a fourth series circuit (third-b series circuit) 14B and a third diode (third-c diode) 131b are connected in parallel, and a second capacitor (second-b capacitor) 15b.

The second-b parallel circuit 12D has a node (third-c end) 122a and a node (third-d end) 122b. The node 122a is electrically connected to the input terminal 51. The input pulse signal is input to the node 122a from the external control device 7. The node 122b is electrically connected to the logic synthesis unit 16B.

The fourth series circuit 14B has the same configuration as the fourth series circuit 14B described in the second embodiment. That is, the fourth series circuit 14B is configured by connecting a fourth diode (third-d diode) 141b and a fourth resistor (third-b resistor) 142b in series. The anode of the fourth diode 141b is connected to the node 122b. The fourth resistor 142b is connected between the cathode of the fourth diode 141b and the node 122a.

The anode of the third diode 131b is connected to the node 122a, and the cathode of the third diode 131b is connected to the node 122b.

The second capacitor 15b is electrically connected between the node 122b and ground.

In the second-b delay circuit 11D, the fourth series circuit 14B functions as a signal path for delaying the falling edge of the input pulse signal, as described in the second embodiment, and the fourth series circuit 14B (specifically, the fourth resistor 142b) and the second capacitor 15b constitute a delay circuit that delays the falling edge of the input pulse signal. In the second-b parallel circuit 12D, only the third diode 131b is connected in parallel with the fourth series circuit 14B as described above, instead of the third series circuit 13B. Therefore, the second-b delay circuit 11D does not have the function of delaying the rising edge of the input pulse signal.

Therefore, the second-b delay circuit 11D is a circuit corresponding to the function of delaying the falling edge of the input pulse signal among the functions of the second delay circuit 11B in the second embodiment. The delay time Td2_{OFF} generated in the falling edge of the input pulse signal by the second-b delay circuit 11D is defined by formula (4) described in the second embodiment.

### [Logic Synthesis Unit]

The logic synthesis unit 16B has an and circuit 161, a first XOR circuit 163a, and a second XOR circuit 163b.

The AND circuit 161 is electrically connected to the first delay circuit 11A. A signal set of the first delayed pulse signals is input to the AND circuit 161. That is, a pair of first delayed pulse signals is input to the AND circuit 161 from the first delay circuit 11A. The AND circuit 161 is a logical product circuit that outputs the first control pulse signal by performing a logical AND operation on the first delayed pulse signals that have been input. The AND circuit 161 is electrically connected to the first GDIC 54a, and the first control pulse signal output from the AND circuit 161 is input to the first GDIC 54a.

The first XOR circuit 163a is electrically connected to the input terminal 51 and the second-a delay circuit 11C. A signal set of the input pulse signal and the second-a delayed pulse signal is input to the first XOR circuit 163a. The first XOR circuit 163a is an exclusive OR circuit that outputs the second-a control pulse signal by performing an exclusive OR operation on the input pulse signal and the second-a delayed pulse signal that have been input. The first XOR circuit 163a is electrically connected to the second-a GDIC 541a, and the second-a control pulse signal output from the first XOR circuit 163a is input to the second-a GDIC 541a.

The second XOR circuit 163b is electrically connected to the input terminal 51 and the second-b delay circuit 11D. A signal set of the input pulse signal and the second-b delayed pulse signal is input to the second XOR circuit 163b. The second XOR circuit 163b is an exclusive OR circuit that outputs the second-b control pulse signal by performing an exclusive OR operation on the input pulse signal and the second-b delayed pulse signal that have been input. The second XOR circuit 163b is electrically connected to the second-b GDIC 541b, and the second-b control pulse signal output from the second XOR circuit 163b is input to the second-b GDIC 541b.

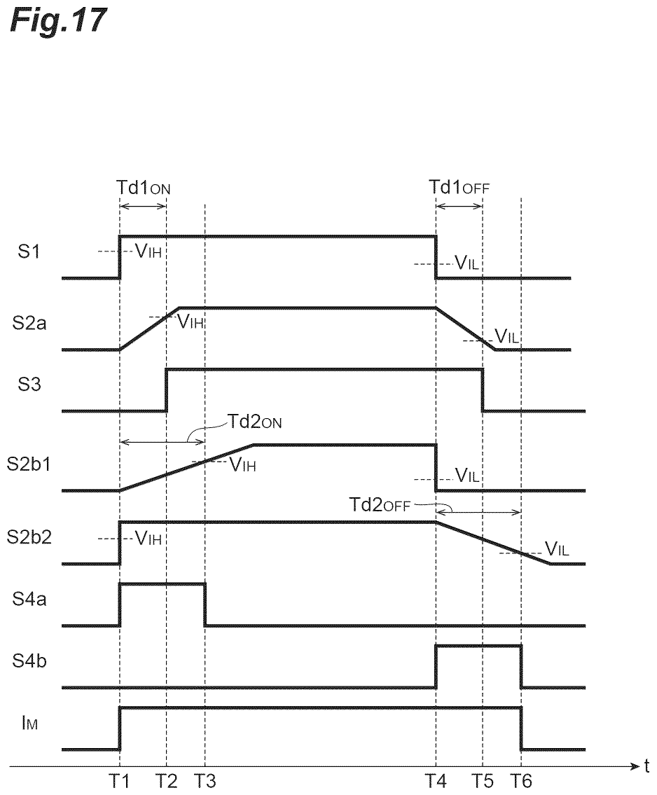

FIG. 17 is a time chart of various signals in the third embodiment. In FIG. 17, the input pulse signal, the first delayed pulse signal, the second-a delayed pulse signal, the second-b delayed pulse signal, the first control pulse signal, the second-a control pulse signal, the second-b control pulse signal, and the main circuit current are represented as input pulse signal S1, first delayed pulse signal S2a, second-a delayed pulse signal S2b1, second-b delayed pulse signal S2b2, first control pulse signal S3, second-a control pulse signal S4a, second-b control pulse signal S4b, and main circuit current I_{M}, respectively. As in the first embodiment, the main circuit current I_{M} is the current flowing through the switch unit 20A.

In FIG. 17, the threshold voltage (threshold signal level) for regarding an input signal as High and the threshold voltage (threshold signal level) for regarding the input signal as Low in the AND circuit 161, the first XOR circuit 163a, and the second XOR circuit 163b are shown as V_{IH} and V_{IL}, respectively. In the AND circuit 161, the first XOR circuit 163a, and the second XOR circuit 163b, once the input signal exceeds V_{IH}, it is regarded as a High state unless it falls below V_{IL}, and once the input signal falls below V_{IL}, it is regarded as a Low state unless it exceeds V_{IH} again. An example of V_{IH} is 3 V, and an example of V_{IL} is 2 V.

In the example shown in FIG. 17 as well, as in the second embodiment, the threshold level that determines the delay time for the rising edge is V_{IH}, which is the same as the threshold voltage for regarding a signal input to the AND circuit 161, the first XOR circuit 163a, and the second XOR circuit 163b as High, and the threshold level that determines the delay time for the falling edge is also V_{IL}, which is the same as the threshold voltage for regarding a signal input to the AND circuit 161, the first XOR circuit 163a, and the second XOR circuit 163b as Low.

As shown in FIG. 17, the input pulse signal S1 has a pulse that rises at time T1 and falls at time T4, as in the second embodiment. When the input pulse signal S1 is input to the delay signal generation unit 10B, the delay signal generation unit 10B generates the first delayed pulse signal S2a, the second-a delayed pulse signal S2b1, and the second-b delayed pulse signal S2b2.

Since the first delay circuit 11A included in the delay signal generation unit 10B has the same configuration as the first delay circuit 11A described in the second embodiment, as shown in FIG. 17, the first delayed pulse signal S2a rises at time T2, which is after a delay time Td1_{ON} from time T1, and falls at time T5, which is after a delay time Td1_{OFF} from time T4, as in the second embodiment.

In the example shown in FIG. 17, the signal level (voltage) of the first delayed pulse signal S2a exceeds the threshold voltage V_{IH} at time T2 and falls below the threshold voltage V_{IL} at time T5. Therefore, in the AND circuit 161, the first delayed pulse signal S2a is processed as a signal that is in a High state from time T2 to time T5, as in the second embodiment, and thereafter maintains a Low state until it exceeds the threshold voltage V_{IH} again.

Based on the first delayed pulse signal S2a generated by the first delay circuit 11A, the first control pulse signal S3 is generated in the same manner as in the second embodiment. Therefore, the first control pulse signal S3 is a pulse signal that rises at time T2 and falls at time T5, as in the second embodiment.

As described above, the second-a delay circuit 11C included in the delay signal generation unit 10B is a circuit corresponding to the function of delaying the rising edge of the input pulse signal among the functions of the second delay circuit 11B in the second embodiment, and does not have the function of delaying the falling edge of the input pulse signal. Therefore, as shown in FIG. 17, the second-a delayed pulse signal S2b1 rises at time T3, which is after a delay time Td2_{ON} from time T1, and falls at time T4.

The second-a delayed pulse signal S2b1 generated by the second-a delay circuit 11C is input to the logic synthesis unit 16B. Specifically, the second-a delayed pulse signal S2b1 is input to the first XOR circuit 163a. The input pulse signal S1 is also input to the first XOR circuit 163a. The first XOR circuit 163a performs an exclusive OR operation on the signal set of the input pulse signal S1 and the second-a delayed pulse signal S2b1 to generate the second-a control pulse signal S4a.

In the example shown in FIG. 17, the signal level (voltage) of the input pulse signal S1 exceeds the threshold voltage V_{IH} at time T1 and falls below the threshold voltage V_{IL} at time T4. Therefore, in the first XOR circuit 163a, the input pulse signal S1 is processed as a signal that is in a High state from time T1 to time T4 and thereafter maintains a Low state until it exceeds the threshold voltage V_{IH} again.

The signal level (voltage) of the second-a delayed pulse signal S2b1 exceeds the threshold voltage V_{IH} at time T3 and falls below the threshold voltage V_{IL} at time T4. Therefore, in the first XOR circuit 163a, the second-a delayed pulse signal S2b1 is processed as a signal that is in a High state from time T3 to time T4 and thereafter maintains a Low state until it exceeds the threshold voltage V_{IH} again.

The second-a control pulse signal S4a is generated by the exclusive OR of the signal set of the input pulse signal S1 and the second-a delayed pulse signal S2b1. From the relationship between the above-described High and Low states of the input pulse signal S1 and the second-a delayed pulse signal S2b1 in the first XOR circuit 163a, the second-a control pulse signal S4a is a pulse signal that rises at time T1 and then falls at time T3.

As described above, the second-b delay circuit 11D included in the delay signal generation unit 10B is a circuit corresponding to the function of delaying the falling edge of the input pulse signal among the functions of the second delay circuit 11B in the second embodiment, and does not have the function of delaying the rising edge of the input pulse signal. Therefore, as shown in FIG. 17, the second-b delayed pulse signal S2b2 rises at time T1 and falls at time T6, which is after a delay time Td2_{OFF} from time T4.

The second-b delayed pulse signal S2b2 generated by the second-b delay circuit 11D is input to the logic synthesis unit 16B. Specifically, the second-b delayed pulse signal S2b2 is input to the second XOR circuit 163b. The input pulse signal S1 is also input to the second XOR circuit 163b. The second XOR circuit 163b performs an exclusive OR operation on the signal set of the input pulse signal S1 and the second-b delayed pulse signal S2b2 to generate the second-b control pulse signal S4b.

In the example shown in FIG. 17, the signal level (voltage) of the input pulse signal S1 exceeds the threshold voltage V_{IH} at time T1 and falls below the threshold voltage V_{IL} at time T4. Therefore, in the second XOR circuit 163b as well, the input pulse signal S1 is processed as a signal that is in a High state from time T1 to time T4, and thereafter maintains a Low state until it exceeds the threshold voltage V_{IH} again.

The signal level (voltage) of the second-b delayed pulse signal S2b2 exceeds the threshold voltage V_{IH} at time T1 and falls below the threshold voltage V_{IL} at time T6. Therefore, in the second XOR circuit 163b, the second-b delayed pulse signal S2b2 is processed as a signal that is in a High state from time T1 to time T6 and thereafter maintains a Low state until it exceeds the threshold voltage V_{IH} again.

The second-b control pulse signal S4b is generated by the exclusive OR of the signal set of the input pulse signal S1 and the second-b delayed pulse signal S2b2. From the relationship between the above-described High and Low states of the input pulse signal S1 and the second-b delayed pulse signal S2b2 in the second XOR circuit 163b, the second-b control pulse signal S4b is a pulse signal that rises at time T4 and then falls at time T6.

In this way, the signal generation circuit 100B can generate the first control pulse signal S3, the second-a control pulse signal S4a, and the second-b control pulse signal S4b based on the same input pulse signal.

In the drive circuit 5B, the first control pulse signal S3 is input to the first GDIC 54a and output as the first output pulse signal. The first output pulse signal output from the first GDIC 54a is input to the first push-pull circuit 55a and output as the first gate signal. The first gate signal is input to the first output terminal 52 via the first gate resistor 56a. Since the first output terminal 52 is electrically connected to the gate of the first switching element 21, the first switching element 21 is driven by the first gate signal.

Since the first output pulse signal is a pulse signal obtained by amplifying the first control pulse signal, the first output pulse signal has the same waveform as the first control pulse signal. Since the first gate signal is a pulse signal obtained by amplifying the first output pulse signal, the first gate signal has the same waveform as the first output pulse signal. Therefore, the first gate signal has the same waveform as the first control pulse signal S3.

In the drive circuit 5B, the second-a control pulse signal S4a is input to the second-a GDIC 541a and output as the second-a output pulse signal. The second-a output pulse signal output from the second-a GDIC 541a is input to the second-a push-pull circuit 551a and output as the second-a gate signal. The second-a gate signal is input to the second-a output terminal 53a via the second-a gate resistor 561a. Since the second-a output terminal 53a is electrically connected to the gate of the second-a switching element 22A, the second-a switching element 22A is driven by the second-a gate signal.

Since the second-a output pulse signal is a pulse signal obtained by amplifying the second-a control pulse signal, the second-a output pulse signal has the same waveform as the second-a control pulse signal. Since the second-a gate signal is a pulse signal obtained by amplifying the second-a output pulse signal, the second-a gate signal has the same waveform as the second-a output pulse signal. Therefore, the second-a gate signal has the same waveform as the second-a control pulse signal S4a.

In the drive circuit 5B, the second-b control pulse signal S4b is input to the second-b GDIC 541b and output as the second-b output pulse signal. The second-b output pulse signal output from the second-b GDIC 541b is input to the second-b push-pull circuit 551b and output as the second-b gate signal. The second-b gate signal is input to the second-b output terminal 53b via the second-b gate resistor 561b. Since the second-b output terminal 53b is electrically connected to the gate of the second-b switching element 22B, the second-b switching element 22B is driven by the second-b gate signal.

Since the second-b output pulse signal is a pulse signal obtained by amplifying the second-b control pulse signal, the second-b output pulse signal has the same waveform as the second-b control pulse signal. Since the second-b gate signal is a pulse signal obtained by amplifying the second-b output pulse signal, the second-b gate signal has the same waveform as the second-b output pulse signal. Therefore, the second-b gate signal has the same waveform as the second-b control pulse signal S4b.

Since the first switching element 21 is driven by the first gate signal having the same waveform as the first control pulse signal S3, it turns on at time T2 and turns off at time T5. Since the second-a switching element 22A is driven by the second-a gate signal having the same waveform as the second-a control pulse signal S4a, it turns on at time T1 and then turns off at time T3. Since the second-b switching element 22B is driven by the second-b gate signal having the same waveform as the second-b control pulse signal S4b, it turns on at time T4 and then turns off at time T6.

Since the first switching element 21, the second-a switching element 22A, and the second-b switching element 22B are driven as described above, the second-a control pulse signal S4a and the second-b control pulse signal S4b are signals that control the second-a switching element 22A and the second-b switching element 22B such that each of the ON-state periods of the second-a switching element 22A and the second-b switching element 22B is shorter than the ON-state period of the first switching element 21, and the ON-state period of the second-b switching element 22B occurs after the ON-state period of the second-a switching element 22A. Furthermore, the first control pulse signal S3 is a signal for controlling the first switching element 21 such that the first switching element 21 transitions from the OFF state to the ON state during the ON-state period of the second-a switching element 22A, and the first switching element 21 transitions from the ON state to the OFF state during the ON-state period of the second-b switching element 22B.

The switch unit 20A is configured by connecting the first switching element 21, the second-a switching element 22A, and the second-b switching element 22B in parallel. Therefore, as in the first embodiment, when any one of the first switching element 21, the second-a switching element 22A, and the second-b switching element 22B is in the ON state, the switch unit 20A is in the ON state, and when all of the first switching element 21, the second-a switching element 22A, and the second-b switching element 22B are in the OFF state, the switch unit 20A is in the OFF state. Therefore, as shown in FIG. 17, the main circuit current I_{M} flows from time T1 to time T6.

The second-a delay circuit 11C included in the delay signal generation unit 10B is a circuit corresponding to the function of delaying the rising edge of the input pulse signal among the functions of the second delay circuit 11B in the second embodiment. The second-a switching element 22A is driven in response to the second-a control pulse signal S4a generated based on the second-a delayed pulse signal S2b1 from the second-a delay circuit 11C. The second-b delay circuit 11D included in the delay signal generation unit 10B is a circuit corresponding to the function of delaying the falling edge of the input pulse signal among the functions of the second delay circuit 11B in the second embodiment. The second-b switching element 22B is driven in response to the second-b control pulse signal S4b generated based on the second-b delayed pulse signal S2b2 from the second-b delay circuit 11D.

Therefore, the third embodiment corresponds to a form in which the turn-on and turn-off functions of the switch unit 20 that were performed by the second switching element 22 in the second embodiment are divided between the second-a switching element 22A and the second-b switching element 22B. Therefore, the drive circuit 5B and the switch unit 20A have the same advantageous effects as in the second embodiment.

The combination of the drive circuit 5B and the switch unit 20A can be applied to the power conversion device 1 shown in FIG. 1 instead of the combination of the drive circuit 5 and the switch unit 20. Since the drive circuit 5B and the switch unit 20A have the same advantageous effects as in the second embodiment, the power conversion device 1 to which the combination of the drive circuit 5B and the switch unit 20A is applied also has the same advantageous effects as in the second embodiment.

### Fourth Embodiment

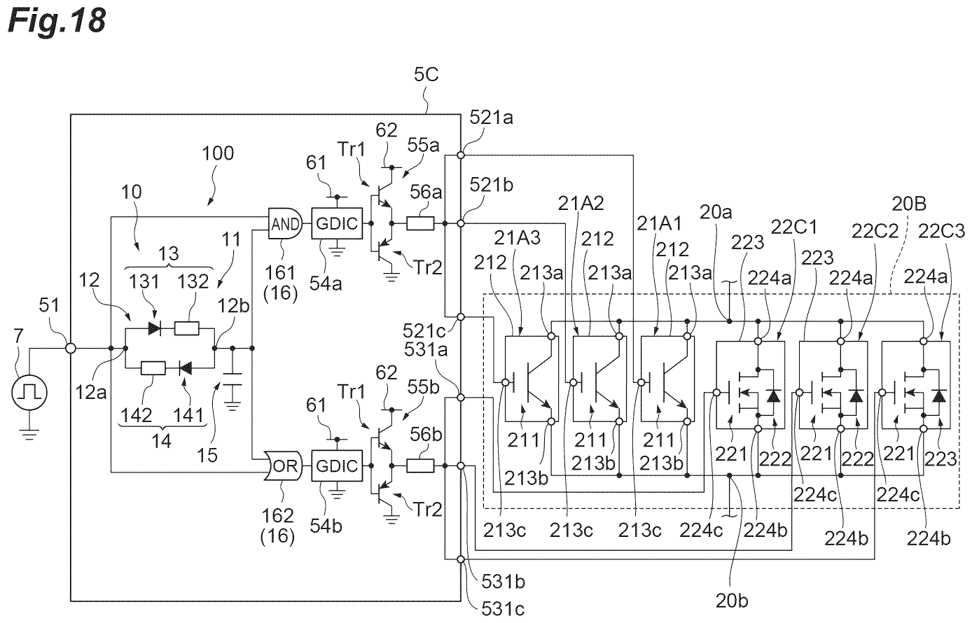

Another example in which the switch unit has a plurality of first switching elements and a plurality of second switching elements will be described as the fourth embodiment. In the fourth embodiment as well, the first switching element is a Si-IGBT and the second switching element is a SiC-MOSFET. In the fourth embodiment, a form in which the switch unit has three first switching elements and three second switching elements will be described. FIG. 18 is a circuit diagram for explaining the fourth embodiment.

The switch unit 20B according to the fourth embodiment has three first switching elements 21A1, 21A2, and 21A3 and three second switching elements 22C1, 22C2, and 22C3. The three first switching elements 21A1, 21A2, and 21A3 have the same configuration and are Si-IGBTs, as in the first embodiment. The three second switching elements 22C1, 22C2, and 22C3 have the same configuration and are SiC-MOSFETs, as in the first embodiment.

The three first switching elements 21A1, 21A2, and 21A3 correspond to the first switching element 21 described in the first embodiment. The first switching elements 21A1, 21A2, and 21A3 have the same configuration. Therefore, the configuration of the first switching element 21A1 will be described, and the description of the configurations of the first switching elements 21A2 and 21A3 will be omitted.

The first switching element 21A1 has an element body 211 and a package 212 housing the element body 211. The element body 211 is a Si-IGBT body (that is, a bare chip of a Si-IGBT) mounted on a semiconductor substrate. Therefore, the element body 211 has a collector (first main terminal), an emitter (second main terminal), and a gate (control terminal). The first switching element 21A1 has a first terminal 213a, a second terminal 213b, and a third terminal 213c for externally connecting the element body 211 housed in the package 212.

The first terminal 213a is electrically connected to the collector of the element body 211.

The second terminal 213b is electrically connected to the emitter of the element body 211.

The third terminal 213c is electrically connected to the gate of the element body 211.

The three second switching elements 22C1, 22C2, and 22C3 correspond to the second switching element 22 described in the first embodiment. The second switching elements 22C1, 22C2, and 22C3 have the same configuration. Therefore, the configuration of the second switching element 22C1 will be described, and the description of the configurations of the second switching elements 22C2 and 22C3 will be omitted.

The second switching element 22C1 has an element body 221 and a package 223 housing the element body 221. The element body 221 is a SiC-MOSFET body (that is, a bare chip of a SiC-MOSFET) mounted on a semiconductor substrate. Therefore, the element body 221 has a drain (first main terminal), a source (second main terminal), and a gate (control terminal). The second switching element 22C1 has a first terminal 224a, a second terminal 224b, and a third terminal 224c for externally connecting the element body 221 housed in the package 223.

The first terminal 224a is electrically connected to the drain of the element body 221.

The second terminal 224b is electrically connected to the source of the element body 221.

The third terminal 224c is electrically connected to the gate of the element body 221.

The second switching element 22C1 may have a freewheeling diode 222 housed inside the package 223. The cathode of the freewheeling diode 222 is electrically connected to the drain (or the first terminal 224a) of the element body 221, and the anode of the freewheeling diode 222 is electrically connected to the source (or the second terminal 224b) of the element body 221. A parasitic diode included in the SiC-MOSFET body may be used as the freewheeling diode.

The three first switching elements 21A1, 21A2, and 21A3 and the three second switching elements 22C1, 22C2, and 22C3 are connected in parallel between the node 20a and the node 20b.

The drive circuit 5C that drives the switch unit 20B differs from the drive circuit 5 according to the first embodiment mainly in that the drive circuit 5C has three first output terminals 521a, 521b, and 521c and three second output terminals 531a, 531b, and 531c.

The drive circuit 5C has the signal generation circuit 100, the first GDIC 54a, the second GDIC 54b, the first push-pull circuit 55a, the second push-pull circuit 55b, the first gate resistor 56a, and the second gate resistor 56b. Since the configurations and functions of the signal generation circuit 100, the first GDIC 54a, the second GDIC 54b, the first push-pull circuit 55a, the second push-pull circuit 55b, the first gate resistor 56a, and the second gate resistor 56b are the same as those in the first embodiment, the description thereof is omitted.

The three first output terminals 521a, 521b, and 521c are electrically connected to the first push-pull circuit 55a via the first gate resistor 56a. Specifically, the three first output terminals 521a, 521b, and 521c are electrically connected via the first gate resistor 56a to the node between the first transistor Tr1 and the second transistor Tr2 of the first push-pull circuit 55a. Therefore, the same first gate signal is input to the first output terminals 521a, 521b, and 521c.

The first output terminal 521a is electrically connected to the third terminal 213c of the first switching element 21A1.

The first output terminal 521b is electrically connected to the third terminal 213c of the first switching element 21A2.

The first output terminal 521c is electrically connected to the third terminal 213c of the first switching element 21A3.

Since the same first gate signal is input to the first output terminals 521a, 521b, and 521c, the same first gate signal is input to the third terminal 213c of each of the first switching elements 21A1, 21A2, and 21A3. That is, the first switching elements 21A1, 21A2, and 21A3 are driven by the same first gate signal.

The three second output terminals 531a, 531b, and 531c are electrically connected to the second push-pull circuit 55b via the second gate resistor 56b. Specifically, the three second output terminals 531a, 531b, and 531c are electrically connected via the second gate resistor 56b to the node between the first transistor Tr1 and the second transistor Tr2 of the second push-pull circuit 55b. Therefore, the same second gate signal is input to the second output terminals 531a, 531b, and 531c.

The second output terminal 531a is electrically connected to the third terminal 224c of the second switching element 22C1.

The second output terminal 531b is electrically connected to the third terminal 224c of the second switching element 22C2.

The second output terminal 531c is electrically connected to the third terminal 224c of the second switching element 22C3.

Since the same second gate signal is input to the second output terminals 531a, 531b, and 531c, the same second gate signal is input to the third terminal 224c of each of the second switching elements 22C1, 22C2, and 22C3. That is, the second switching elements 22C1, 22C2, and 22C3 are driven by the same second gate signal.

Since the signal generation circuit 100 included in the drive circuit 5C is the same as the signal generation circuit 100 described in the first embodiment, the signal generation circuit 100 has the same advantageous effects as in the first embodiment. Furthermore, the drive circuit 5C is the same as the drive circuit 5 described in the first embodiment except that it outputs the first gate signal from the three first output terminals 521a, 521b, and 521c and outputs the second gate signal from the three second output terminals 531a, 531b, and 531c. Therefore, the drive circuit 5C also has the same advantageous effects as the drive circuit 5 described in the first embodiment.

The first switching elements 21A1, 21A2, and 21A3 that are included in the switch unit 20B and driven by the first gate signal correspond to the first switching element 21 described in the first embodiment, and the second switching elements 22C1, 22C2, and 22C3 driven by the second gate signal correspond to the second switching element 22 described in the first embodiment. Therefore, the switch unit 20B corresponds to a form in which three first switching elements 21 and three second switching elements 22 are connected in parallel. Therefore, the switch unit 20B driven by the drive circuit 5C has the same advantageous effects as the switch unit 20 described in the first embodiment.

The combination of the switch unit 20B and the drive circuit 5C described in the fourth embodiment can be applied to the power conversion device 1 shown in FIG. 1 instead of the drive circuit 5 and the switch unit 20. As described above, since the advantageous effects of the switch unit 20B and the drive circuit 5C are the same as those of the switch unit 20 and the drive circuit 5 in the first embodiment, the power conversion device 1 to which the combination of the switch unit 20B and the drive circuit 5C is applied instead of the drive circuit 5 and the switch unit 20 also has the same advantageous effects as in the first embodiment.

The switch unit 20B has the three first switching elements 21A1, 21A2, and 21A3 and the three second switching elements 22C1, 22C2, and 22C3, and they are connected in parallel. Therefore, it is easy to allow a larger current to flow through the switch unit 20B.

### Fifth Embodiment

Yet another example of a case where the switch unit has a plurality of first switching elements and a plurality of second switching elements will be described as the fifth embodiment. In the fifth embodiment as well, the first switching element is a Si-IGBT and the second switching element is a SiC-MOSFET.

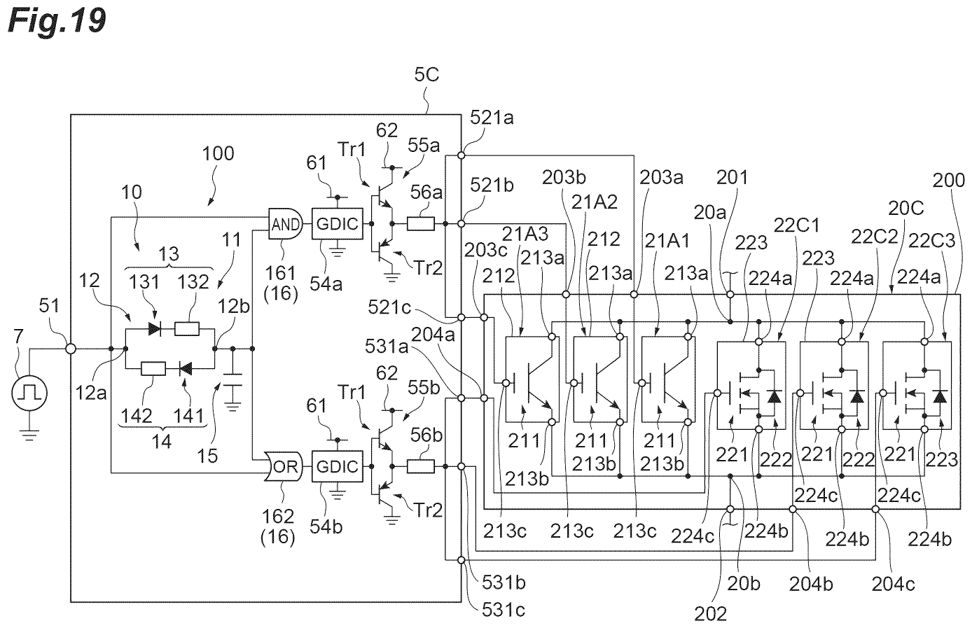

FIG. 19 is a circuit diagram for explaining the fifth embodiment. FIG. 19 shows a switch unit 20C according to the fifth embodiment and a drive circuit 5C for driving the switch unit 20C. Since the drive circuit 5C is the same as that in the fourth embodiment, the description of the drive circuit 5C is omitted.

The switch unit 20C differs from the switch unit 20B described in the fourth embodiment mainly in that the first switching elements 21A1, 21A2, and 21A3 and the second switching elements 22C1, 22C2, and 22C3 described in the fourth embodiment are housed in a package 200. That is, the switch unit 20C is configured as a semiconductor module (or switching module) including the first switching elements 21A1, 21A2, and 21A3 and the second switching elements 22C1, 22C2, and 22C3.

The package 200 has a first terminal 201, a second terminal 202, a third terminal 203a, a fourth terminal 203b, a fifth terminal 203c, a sixth terminal 204a, a seventh terminal 204b, and an eighth terminal 204c for externally connecting the first switching elements 21A1, 21A2, and 21A3 and the second switching elements 22C1, 22C2, and 22C3 housed inside the package 200.

The first terminal 201 is electrically connected to the node 20a. The second terminal 202 is electrically connected to the node 20b. The first terminal 201 may serve as the node 20a, or the second terminal 202 may serve as the node 20b.

The third terminal 203a is electrically connected to the third terminal 213c of the first switching element 21A1 and is also electrically connected to the first output terminal 521a of the drive circuit 5C. Therefore, the first gate signal from the first output terminal 521a is input to the third terminal 213c of the first switching element 21A1.

The fourth terminal 203b is electrically connected to the third terminal 213c of the first switching element 21A2 and is also electrically connected to the first output terminal 521b of the drive circuit 5C. Therefore, the first gate signal from the first output terminal 521b is input to the third terminal 213c of the first switching element 21A2.

The fifth terminal 203c is electrically connected to the third terminal 213c of the first switching element 21A3 and is also electrically connected to the first output terminal 521c of the drive circuit 5C. Therefore, the first gate signal from the first output terminal 521c is input to the third terminal 213c of the first switching element 21A3.

The sixth terminal 204a is electrically connected to the third terminal 224c of the second switching element 22C1 and is also electrically connected to the second output terminal 531a of the drive circuit 5C. Therefore, the second gate signal from the second output terminal 531a is input to the third terminal 224c of the second switching element 22C1.

The seventh terminal 204b is electrically connected to the third terminal 224c of the second switching element 22C2 and is also electrically connected to the second output terminal 531b of the drive circuit 5C. Therefore, the second gate signal from the second output terminal 531b is input to the third terminal 224c of the second switching element 22C2.

The eighth terminal 204c is electrically connected to the third terminal 224c of the second switching element 22C3 and is also electrically connected to the second output terminal 531c of the drive circuit 5C. Therefore, the second gate signal from the second output terminal 531c is input to the third terminal 224c of the second switching element 22C3.

The switch unit 20C described in the fifth embodiment is the same as the switch unit 20B according to the fourth embodiment except that the first switching elements 21A1, 21A2, and 21A3 and the second switching elements 22C1, 22C2, and 22C3 are housed in the package 200. Furthermore, the drive circuit 5C is also the same as in the fourth embodiment. Therefore, the switch unit 20C driven by the drive circuit 5C has the same advantageous effects as in the fourth embodiment.

The combination of the switch unit 20C and the drive circuit 5C can be applied to the power conversion device 1 shown in FIG. 1 instead of the drive circuit 5 and the switch unit 20. The power conversion device 1 to which the combination of the switch unit 20C and the drive circuit 5C is applied instead of the combination of the drive circuit 5 and the switch unit 20 also has the same advantageous effects as in the fourth embodiment.

### Sixth Embodiment

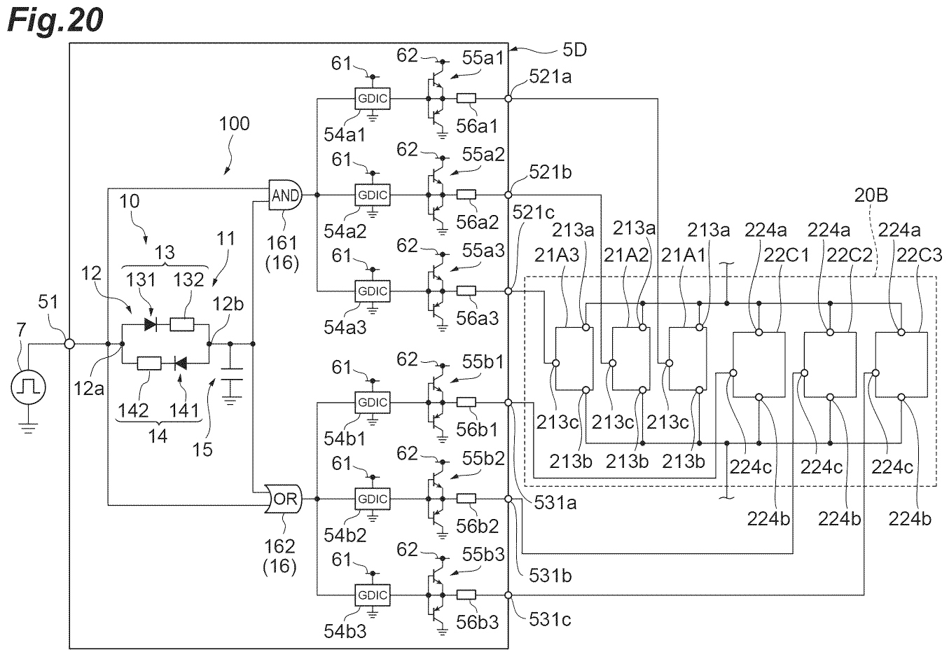

A modification of the drive circuit will be described as the sixth embodiment. FIG. 20 is a circuit diagram for explaining the sixth embodiment.

The drive circuit 5D according to the sixth embodiment is a circuit for driving the switch unit 20B described in the fourth embodiment. That is, the drive circuit 5D is a modification of the drive circuit 5C.

The drive circuit 5D differs from the drive circuit 5C described in the fourth embodiment mainly in that a set of a first GDIC, a first push-pull circuit, and a first gate resistor is provided corresponding to each of the three first output terminals 521a, 521b, and 521c, and a set of a second GDIC, a second push-pull circuit, and a second gate resistor is provided corresponding to each of the three second output terminals 531a, 531b, and 531c. The drive circuit 5D will be described focusing on this difference.

The drive circuit 5D has the signal generation circuit 100. Since the configuration and function of the signal generation circuit 100 are the same as in the first embodiment, the description thereof is omitted.

The drive circuit 5D has a first GDIC 54a1, a first GDIC 54a2, and a first GDIC 54a3 that are electrically connected to the AND circuit 161 and to which the first output pulse signal from the AND circuit 161 is input. Each of the first GDIC 54a1, the first GDIC 54a2, and the first GDIC 54a3 is connected between the first power supply potential line 61 and ground. The first GDIC 54a1, the first GDIC 54a2, and the first GDIC 54a3 have the same configuration as the first GDIC 54a described in the first embodiment and generate the first output pulse signal from the input first control pulse signal.

The drive circuit 5D has a first push-pull circuit 55a1 and a first gate resistor 56a1 provided corresponding to the first GDIC 54a1, a first push-pull circuit 55a2 and a first gate resistor 56a2 provided corresponding to the first GDIC 54a2, and a first push-pull circuit 55a3 and a first gate resistor 56a3 provided corresponding to the first GDIC 54a3.

Each of the first push-pull circuit 55a1, the first push-pull circuit 55a2, and the first push-pull circuit 55a3 is connected between the second power supply potential line 62 and ground. The first push-pull circuit 55a1, the first push-pull circuit 55a2, and the first push-pull circuit 55a3 have the same configuration as the first push-pull circuit 55a described in the first embodiment, and are configured by connecting the first transistor Tr1 and the second transistor Tr2 in series between the second power supply potential line 62 and ground. The first push-pull circuit 55a1, the first push-pull circuit 55a2, and the first push-pull circuit 55a3 generate the first gate signal from the input first output pulse signal.

The first gate signal generated by the first push-pull circuit 55a1 is input to the first output terminal 521a via the first gate resistor 56a1.

The first gate signal generated by the first push-pull circuit 55a2 is input to the first output terminal 521b via the first gate resistor 56a2.

The first gate signal generated by the first push-pull circuit 55a3 is input to the first output terminal 521c via the first gate resistor 56a3.

An example of the resistance value of each of the first gate resistor 56a1, the first gate resistor 56a2, and the first gate resistor 56a3 is the same as that of the first gate resistor 56a in the first embodiment. The first gate resistor 56a1, the first gate resistor 56a2, and the first gate resistor 56a3 may be the same as or different from each other.

The drive circuit 5D has a second GDIC 54b1, a second GDIC 54b2, and a second GDIC 54b3 that are electrically connected to the OR circuit 162 and to which the second output pulse signal from the OR circuit 162 is input. Each of the second GDIC 54b1, the second GDIC 54b2, and the second GDIC 54b3 is connected between the first power supply potential line 61 and ground. The second GDIC 54b1, the second GDIC 54b2, and the second GDIC 54b3 have the same configuration as the second GDIC 54b described in the first embodiment and generate the second output pulse signal from the input second control pulse signal.

The drive circuit 5D has a second push-pull circuit 55b1 and a second gate resistor 56b1 provided corresponding to the second GDIC 54b1, a second push-pull circuit 55b2 and a second gate resistor 56b2 provided corresponding to the second GDIC 54b2, and a second push-pull circuit 55b3 and a second gate resistor 56b3 provided corresponding to the second GDIC 54b3.

Each of the second push-pull circuit 55b1, the second push-pull circuit 55b2, and the second push-pull circuit 55b3 is connected between the second power supply potential line 62 and ground. The second push-pull circuit 55b1, the second push-pull circuit 55b2, and the second push-pull circuit 55b3 have the same configuration as the second push-pull circuit 55b described in the first embodiment, and are configured by connecting the first transistor Tr1 and the second transistor Tr2 in series between the second power supply potential line 62 and ground. The second push-pull circuit 55b1, the second push-pull circuit 55b2, and the second push-pull circuit 55b3 generate the second gate signal from the input second output pulse signal.

The second gate signal generated by the second push-pull circuit 55b1 is input to the second output terminal 531a via the second gate resistor 56b1.

The second gate signal generated by the second push-pull circuit 55b2 is input to the second output terminal 531b via the second gate resistor 56b2.

The second gate signal generated by the second push-pull circuit 55b3 is input to the second output terminal 531c via the second gate resistor 56b3.

In the drive circuit 5D having the above configuration, as in the case of the drive circuit 5C, the first gate signal can be output from the three first output terminals 521a, 521b, and 521c, and the second gate signal can be output from the three second output terminals 531a, 531b, and 531c. Therefore, the drive circuit 5D can drive the switch unit 20B in the same manner as the drive circuit 5C. That is, the drive circuit 5D has the same advantageous effects as the drive circuit 5C.

The combination of the switch unit 20B and the drive circuit 5D described in the sixth embodiment can be applied to the power conversion device 1 shown in FIG. 1 instead of the drive circuit 5 and the switch unit 20. The power conversion device 1 to which the combination of the switch unit 20B and the drive circuit 5D described in the sixth embodiment is applied instead of the combination of the drive circuit 5 and the switch unit 20 has the same advantageous effects as in the fourth embodiment.

The set of a GDIC and a push-pull circuit (GDIC, push-pull circuit, and gate resistor) provided at the subsequent stage of the signal generation circuit 100 (specifically, at the subsequent stage of the logic synthesis unit 16) functions as an amplifier for the control pulse signal generated by the signal generation circuit 100.

In the configuration of the drive circuit 5D, a set of a GDIC, a push-pull circuit, and a gate resistor is provided corresponding to each of the first switching elements 21A1, 21A2, and 21A3, and a set of a GDIC, a push-pull circuit, and a gate resistor is provided corresponding to each of the second switching elements 22C1, 22C2, and 22C3.

For example, corresponding to the first switching element 21A1, the drive circuit 5D has the first GDIC 54a1, the first push-pull circuit 55a1, and the first gate resistor 56a1. Corresponding to the second switching element 22C1, the drive circuit 5D has the second GDIC 54b1, the second push-pull circuit 55b1, and the second gate resistor 56b1. The correspondence relationship has been described using the first switching element 21A1 and the second switching element 22C1 as examples, but the same applies to the first switching elements 21A2 and 21A3 and the second switching elements 22C2 and 22C3.

Therefore, in the configuration of the drive circuit 5D, the amplification factor when generating the first gate signal from the first control pulse signal can be adjusted according to each of the first switching elements 21A1, 21A2, and 21A3. Similarly, in the configuration of the drive circuit 5D, the amplification factor when generating the second gate signal from the second control pulse signal can be adjusted according to each of the second switching elements 22C1, 22C2, and 22C3.

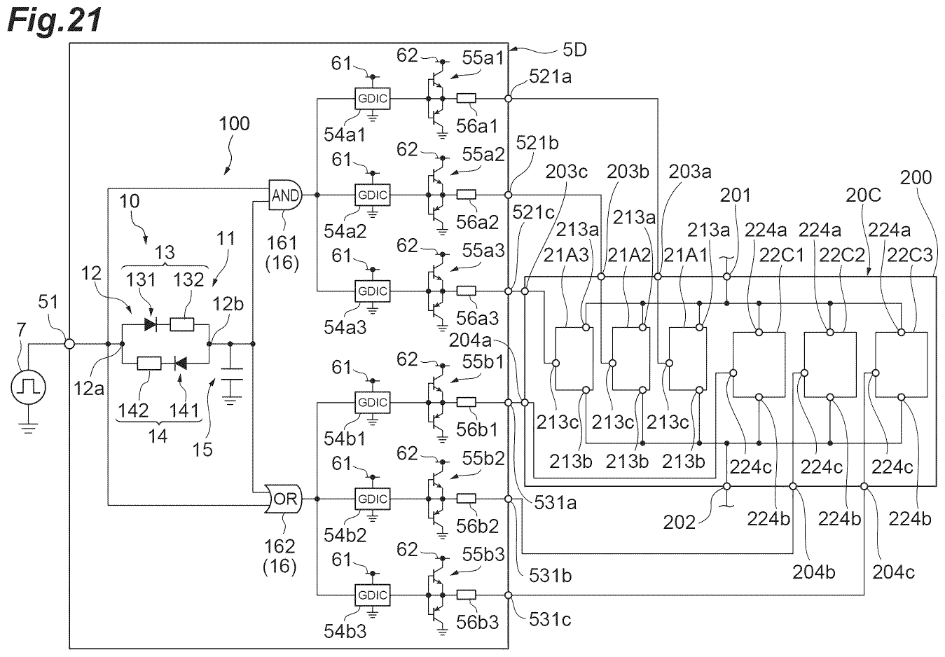

FIG. 21 is a drawing for explaining a modification of the sixth embodiment. As shown in FIG. 21, the drive circuit 5D can also be applied to the switch unit 20C described in the fifth embodiment instead of the switch unit 20B.

### Seventh Embodiment

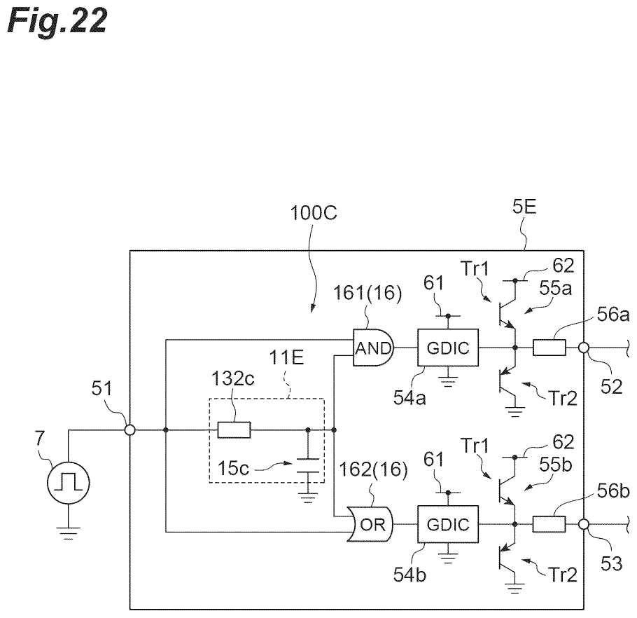

A modification of the signal generation circuit will be described as the seventh embodiment. FIG. 22 is a circuit diagram for explaining the seventh embodiment. The drive circuit 5E shown in FIG. 22 has the same configuration as the drive circuit 5 except that it includes a signal generation circuit 100C instead of the signal generation circuit 100.

The signal generation circuit 100C has a delay circuit 11E and the logic synthesis unit 16. Since the logic synthesis unit 16 is the same as in the first embodiment, the description thereof is omitted.

The delay circuit 11E is composed of a resistor 132c and a capacitor 15c. An example of the resistance value of the resistor 132c is the same as that of the first resistor 132 in the first embodiment. An example of the capacitance of the capacitor 15c is the same as that of the capacitor 15 in the first embodiment.

The first end of the resistor 132c is electrically connected to the input terminal 51, and the second end of the resistor 132c (the end opposite to the first end) is electrically connected to the first end of the capacitor 15c. The second end of the capacitor 15c (the end opposite to the first end) is electrically connected to ground. The node between the resistor 132c and the capacitor 15c is electrically connected to the AND circuit 161 and the OR circuit 162.

In the configuration of the delay circuit, a delayed signal is generated in which the rising edge and the falling edge of the input pulse signal are delayed by a delay time defined by the resistance value of the resistor 132c and the capacitance of the capacitor 15c. In the configuration of the delay circuit 11E, the delay time for the rising edge and the falling edge of the input pulse signal is the same. That is, the delay circuit 11E does not have the function of individually adjusting the delay time for the rising edge and the delay time for the falling edge of the input pulse signal. The delayed pulse signal generated by the delay circuit 11E is input to the AND circuit 161 and the OR circuit 162.

The signal generation circuit 100C is the same as the signal generation circuit 100 according to the first embodiment except that the delay circuit 11E is used instead of the delay circuit 11. Therefore, the signal generation circuit 100C can generate a first control pulse signal and a second control pulse signal that are different from each other from one input pulse signal, similarly to the signal generation circuit 100.

The drive circuit 5E is the same as the drive circuit 5 according to the first embodiment except that the signal generation circuit 100C is used instead of the signal generation circuit 100. Therefore, in the drive circuit 5E, as in the case of the drive circuit 5, it is possible to generate the first gate signal from the first control pulse signal generated by the signal generation circuit 100C and to generate the second gate signal from the second control pulse signal.

Therefore, the advantageous effects of the signal generation circuit 100C and the drive circuit 5E including the signal generation circuit 100C with respect to the point that a first control pulse signal and a second control pulse signal that are different from each other and the first gate signal and second gate signal corresponding thereto can be generated from one input pulse signal are the same as those of the signal generation circuit 100 and the drive circuit 5 of the first embodiment.

The advantageous effects obtained when the switch unit 20 is driven by the drive circuit 5E, and the advantageous effects of the power conversion device 1 to which the combination of the drive circuit 5E and the switch unit 20 is applied instead of the combination of the drive circuit 5 and the switch unit 20 shown in FIG. 1 are the same as those in the first embodiment.

The delay circuit 11E has, for example, a simpler configuration than the delay circuit 11 described in the first embodiment. Therefore, when there is no need to individually adjust the delay time for the rising edge and the falling edge of the input pulse signal, the drive circuit 5E can be easily manufactured by adopting the delay circuit 11E.

### Eighth Embodiment

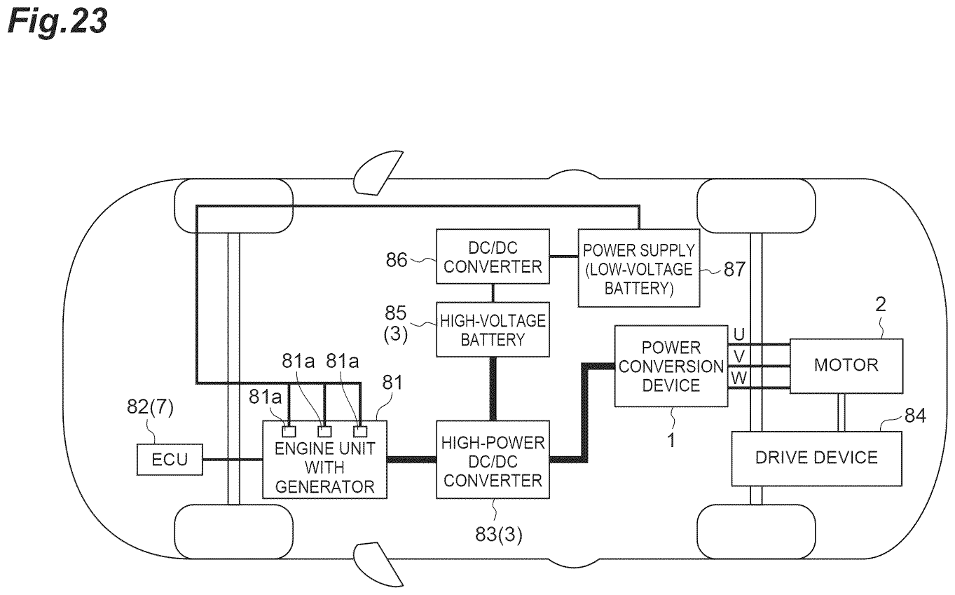

As the eighth embodiment, a configuration example of a vehicle X to which the power conversion device 1 shown in FIG. 1 is applied will be described. FIG. 23 is a diagram showing a configuration example of a vehicle on which the power conversion device 1 is mounted.

The vehicle X includes an engine unit with generator 81, an ECU 82, a high-power DC/DC converter 83, the power conversion device 1, the motor 2, a drive device 84, a high-voltage battery 85, a DC/DC converter 86, and a power supply 87. The mounting positions of the components in FIG. 23 differ from the actual positions for convenience of illustration. The vehicle X shown in FIG. 23 is a so-called series hybrid vehicle.

The engine unit with generator 81 includes a generator, an engine dedicated to power generation that drives the generator, and an engine ignition device 81a. Since the energy conversion efficiency of the engine changes significantly at the timing of ignition, it is necessary for the ECU 82 to control the ignition timing in consideration of the rotation angle of the crank that converts the reciprocating motion of the piston in the cylinder into rotational motion and the required amount of power generation. Therefore, the engine ignition device 81a is provided for each cylinder of the engine.

The high-power DC/DC converter 83 converts the DC power generated by the generator of the engine unit with generator 81 into high-voltage DC power. The high-power DC/DC converter 83 supplies the high-voltage DC power to the power conversion device 1 and the high-voltage battery 85. The high-power DC/DC converter 83 can supply the discharge power discharged from the high-voltage battery 85 to the power conversion device 1. The high-power DC/DC converter 83 can also charge the high-voltage battery 85 with the regenerative power supplied from the power conversion device 1 when the vehicle X decelerates. Therefore, the high-power DC/DC converter 83, or the high-power DC/DC converter 83 and the high-voltage battery 85, function as the DC power supply unit 3 shown in FIG. 1.

The power conversion device 1 receives DC power from the high-power DC/DC converter 83 and converts the received DC power into three-phase AC power. The control of the power conversion device 1 is performed by the ECU 82. Therefore, the ECU 82 functions as the external control device 7 shown in FIG. 1. In FIG. 23, since the configuration example of the vehicle X to which the power conversion device 1 is applied is schematically shown, the engine unit with generator 81 and the high-power DC/DC converter 83 are illustrated as being interposed between the ECU 82 and the power conversion device 1; however, the ECU 82 only needs to be electrically connected to the drive circuit 5 (see FIG. 1) of the power conversion device 1 so that the input pulse signal generated by the ECU 82 is supplied to the drive circuit 5 (see FIG. 1). Therefore, the input pulse signal may be supplied from the ECU 82 to the power conversion device 1 using a communication line shared with the engine unit with generator 81 and the like, or the input pulse signal may be supplied from the ECU 82 to the power conversion device 1 via a communication line independent of the engine unit with generator 81 and the like.

The motor 2 has a shaft and rotates the shaft using the three-phase AC power supplied from the power conversion device 1.

The drive device 84 transmits the power generated by the rotation of the shaft of the motor 2 to the drive wheels of the vehicle X. In FIG. 23, the rear wheels of the vehicle X are the drive wheels, but the drive wheels are not limited to the rear wheels. That is, the front wheels may be the drive wheels, or both the front wheels and the rear wheels may be the drive wheels.

The DC/DC converter 86 receives DC power from the high-power DC/DC converter 83 and converts the received DC power into low-voltage DC power. The power supply 87, which is a low-voltage battery, is charged by the low-voltage DC power output from the DC/DC converter 86. The discharge power discharged from the power supply 87 is supplied to the engine ignition device 81a and the like.

The vehicle on which the power conversion device 1 according to the embodiment is mounted is not limited to a hybrid vehicle such as the vehicle X shown in FIG. 23 and may be any vehicle equipped with an engine.

According to the embodiments described above, it is possible to provide a technology capable of generating the first control pulse signal and the second control pulse signal for controlling two switching elements having different characteristics from one input pulse signal.

Various embodiments according to one aspect of the present disclosure have been described above, but these are merely specific examples used to clarify the technical content of the present disclosure, and the present disclosure should not be interpreted as being limited to these specific examples, and the scope of the present disclosure is limited only by the appended claims.

In the various embodiments exemplified above, a package integrating the signal generation circuit included in the drive circuit and a plurality of GDICs may be configured as a new GDIC. Each of the drive circuits exemplified in the various embodiments may be configured as a new GDIC.

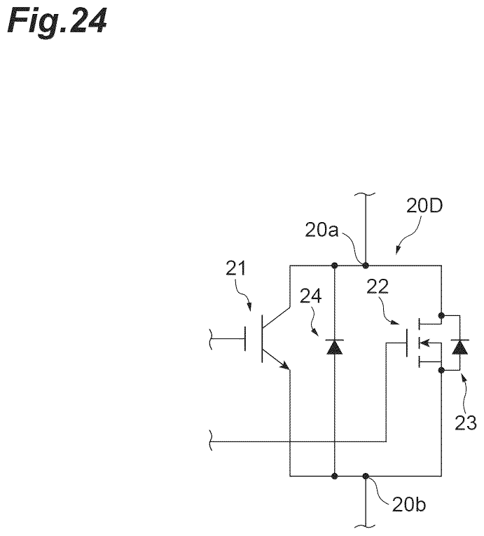

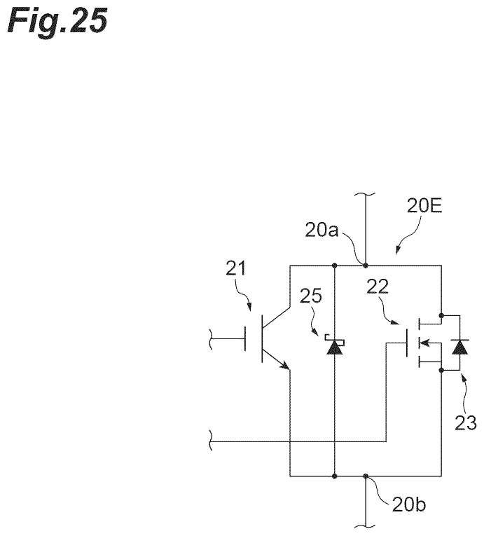

The switch unit may have elements other than the first switching element and the second switching element. For example, as in the switch unit 20D shown in FIG. 24, a freewheeling diode 24 may be further connected in parallel with the first switching element 21 and the second switching element 22 between the node 20a and the node 20b. Alternatively, as in the switch unit 20E shown in FIG. 25, a Schottky barrier diode 25 may be connected in parallel with the first switching element 21 and the second switching element 22 between the node 20a and the node 20b.

The delay signal generation unit is configured to generate at least one delayed pulse signal using a common input pulse signal for the first switching element and the second switching element having different transition times between the ON state, which is a conductive state, and the OFF state, which is a non-conductive state, and the logic synthesis unit only needs to be configured to generate the first control pulse signal for the first switching element and the second control pulse signal for the second switching element by performing different logic synthesis operations on two signal sets among a plurality of signal sets defined by the at least one delayed pulse signal and the input pulse signal.

In this case, since different logic synthesis operations are performed on two signal sets among the plurality of signal sets defined by the at least one delayed pulse signal and the input pulse signal, a first control pulse signal and a second control pulse signal that are different from each other can be generated from one input pulse signal.

Examples of the plurality of signal sets defined by the at least one delayed pulse signal and the input pulse signal include a signal set of the delayed pulse signal and the input pulse signal, a signal set of two identical delayed pulse signals, and a signal set of two identical input pulse signals. When the delay signal generation unit generates delayed pulse signals having different delay states, the different delayed pulse signals may be adopted as a signal set.

The logic synthesis unit may be configured to generate the second control pulse signal based on a set of the delayed pulse signal and the input pulse signal or a set of the delayed pulse signals when generating the first control pulse signal based on a set of the delayed pulse signal and the input pulse signal, and may be configured to generate the second control pulse signal based on a set of the delayed pulse signal and the input pulse signal when generating the first control pulse signal based on a set of the delayed pulse signals.

The logic synthesis described above may be logical negation in addition to the exemplified logical AND, logical OR, and exclusive OR. For example, when it is necessary to invert the logical state of the delayed pulse signal due to the characteristics of the circuit employed, the logical negation can be used. Therefore, the logic synthesis unit may include, for example, at least two of an AND circuit, an OR circuit, an XOR circuit, and a NOT circuit.

From the viewpoint of utilizing the high-speed switching characteristics of the SiC-MOSFET for the turn-on and turn-off of the switch unit, the case where the first switching element is a Si-IGBT and the second switching element is a SiC-MOSFET has been described. However, the first switching element may be a SiC-MOSFET and the second switching element may be a Si-IGBT.

When the delay circuit of the delay signal generation unit has a parallel circuit together with a capacitor, the parallel circuit may be, as exemplified, a parallel circuit of a resistor and a series circuit of a diode and a resistor.

In the various embodiments described above (including modifications), one or more elements of one embodiment may be combined with one or more elements of another embodiment.

The following shows feature examples extracted from the description of this specification and the drawings.

### [A1] (First Embodiment, FIG. 2)

A signal generation circuit, comprising:
a delay signal generation unit (10) configured to generate at least one delayed pulse signal using a common input pulse signal for a first switching element (21) and a second switching element (22) having different transition times between an ON state, which is a conductive state, and an OFF state, which is a non-conductive state; and
a logic synthesis unit (16) configured to generate a first control pulse signal for the first switching element and a second control pulse signal for the second switching element by performing different logic synthesis operations on two signal sets among a plurality of signal sets defined by the at least one delayed pulse signal and the input pulse signal,
wherein the first control pulse signal is different from the input pulse signal, and
the second control pulse signal is different from the input pulse signal and the first control pulse signal.

### [A2] (First Embodiment, FIG. 2, Seventh Embodiment, FIG. 22)

The signal generation circuit according to [A1], wherein the delay signal generation unit has at least one delay circuit (11, 11E) including a resistor (132, 142, 132c) and a capacitor (15, 15c).

[A3] (first Embodiment, FIG. 2)

The signal generation circuit according to [A1], wherein the delay signal generation unit has at least one delay circuit (11), and
the delay circuit has:
a resistance unit (12) configured to have two signal paths connected in parallel and to have resistances respectively for delaying a rising edge and delaying a falling edge of a pulse of the input pulse signal; and
a capacitor (15).

### [A4] (First Embodiment, FIG. 2, Second Embodiment, FIG. 9)

The signal generation circuit according to any one of [A1] to [A3], wherein the logic synthesis unit has at least two of an AND circuit (161), an OR circuit (162), and an XOR circuit (163) in order to perform the different logic synthesis operations.

### [A5]

The signal generation circuit according to any one of [A1] to [A4], wherein the second switching element is a switching element having a shorter transition time than the first switching element.

### [A6]

The signal generation circuit according to any one of [A1] to [A5], wherein the first switching element is an insulated gate bipolar transistor, and
the second switching element is a metal-oxide-semiconductor field-effect transistor.

### [A7]

The signal generation circuit according to any one of [A1] to [A6], wherein the logic synthesis unit is configured to generate the first control pulse signal and the second control pulse signal such that the second switching element turns on before the first switching element turns on and the second switching element turns off after the first switching element turns off.

### [A8] (First Embodiment, FIG. 2, Second Embodiment, FIG. 9)

The signal generation circuit according to [A1], wherein the delay signal generation unit has a delay circuit (11) that generates the delayed pulse signal,
the two signal sets are a set of the delayed pulse signal and the input pulse signal or a set of the delayed pulse signals, and
the logic synthesis unit (16, 16a) is:
   configured to generate the second control pulse signal based on a set of the delayed pulse signal and the input pulse signal or a set of the delayed pulse signals when generating the first control pulse signal based on a set of the delayed pulse signal and the input pulse signal; and
   configured to generate the second control pulse signal based on a set of the delayed pulse signal and the input pulse signal when generating the first control pulse signal based on a set of the delayed pulse signals.

### [A9] (First Embodiment, FIG. 2)

The signal generation circuit according to [A8], wherein the delay circuit has:
a parallel circuit (12) in which a first series circuit (13) of a first diode (131) and a first resistor (132) and a second series circuit (14) of a second diode (141) and a second resistor (142) are connected in parallel, the parallel circuit (12) having a first end (12a) to which the input pulse signal is input and a second end (12b) electrically connected to the logic synthesis unit; and
a capacitor (15) electrically connected between the second end and ground,
wherein an anode of the first diode is electrically connected to the first end,
the first resistor is disposed between a cathode of the first diode and the second end,
an anode of the second diode is electrically connected to the second end, and
the second resistor is disposed between a cathode of the second diode and the first end.

### [A10] (First Embodiment, FIG. 2)

The signal generation circuit according to [A9], wherein the logic synthesis unit has:
an AND circuit (161) that receives the delayed pulse signal and the input pulse signal as inputs and outputs the first control pulse signal; and
an OR circuit (162) that receives the delayed pulse signal and the input pulse signal as inputs and outputs the second control pulse signal.

### [A11] (Third Embodiment, FIG. 16, FIG. 17)

The signal generation circuit according to any one of [A1] to [A6], wherein the logic synthesis unit is configured to generate the first control pulse signal and the second control pulse signal such that the first switching element turns on in a first ON state among two ON states of the second switching element and the first switching element turns off in a second ON state, which is after the first ON state, among the two ON states of the second switching element.

### [A12] (Second Embodiment, FIG. 9)

The signal generation circuit according to [A1], wherein the delay signal generation unit (10A) has:
a first delay circuit (11A) that generates a first delayed pulse signal; and
a second delay circuit (11B) that generates a second delayed pulse signal different from the first delayed pulse signal, and
the logic synthesis unit (16A) is configured to generate the first control pulse signal based on a set of the first delayed pulse signals and generates the second control pulse signal based on a set of the second delayed pulse signal and the input pulse signal.

### [A13] (Second Embodiment, FIG. 9)

The signal generation circuit according to [A12], wherein the first delay circuit (11A) has:
a first parallel circuit (12A) having a first end (12c) to which the input pulse signal is input and a second end (12d) electrically connected to the logic synthesis unit, in which a first series circuit (13A) of a first diode (131a) and a first resistor (132a) and a second series circuit (14A) of a second diode (141a) and a second resistor (142a) are connected in parallel; and
a first capacitor (15a) electrically connected between the second end and ground,
wherein an anode of the first diode is connected to the first end,
the first resistor is disposed between a cathode of the first diode and the second end,
an anode of the second diode is connected to the second end, and
the second resistor is disposed between a cathode of the second diode and the first end, and
the second delay circuit (11B) has:
   a second parallel circuit (12B) having a third end (12e) to which the input pulse signal is input and a fourth end (12f) electrically connected to the logic synthesis unit, in which a third series circuit (13B) of a third diode (131b) and a third resistor (132b) and a fourth series circuit (14B) of a fourth diode (141b) and a fourth resistor (142b) are connected in parallel; and
   a second capacitor (15b) electrically connected between the fourth end and ground,
   wherein an anode of the third diode is connected to the third end,
   the third resistor is disposed between a cathode of the third diode and the fourth end,
   an anode of the fourth diode is connected to the fourth end, and
   the fourth resistor is disposed between a cathode of the fourth diode and the third end.

### [A14] (Second Embodiment, FIG. 9)

The signal generation circuit according to [A12] or [A13], wherein the logic synthesis unit (16A) has:
an AND circuit (161) that receives two of the first delayed pulse signals as inputs and outputs the first control pulse signal; and
an XOR circuit (163) that receives the second delayed pulse signal and the input pulse signal as inputs and outputs the second control pulse signal.

### [A15] (Second Embodiment, FIG. 2)

A drive circuit, comprising:
the signal generation circuit (100) according to any one of [A1] to [A14];
a first driver (54a) that generates a first output pulse signal for driving the first switching element in response to the first control pulse signal generated by the signal generation circuit; and
a second driver (54b) that generates a second output pulse signal for driving the second switching element in response to the second control pulse signal generated by the signal generation circuit.

### [A16] (Second Embodiment, FIG. 2)

The drive circuit according to [A15], comprising:
a first push-pull circuit (55a) that is driven by the first output pulse signal and generates a first drive pulse signal for driving the first switching element; and
a second push-pull circuit (55b) that is driven by the second output pulse signal and generates a second drive pulse signal for driving the second switching element.

### [A17] (First Embodiment, FIG. 1, FIG. 2)

A power conversion device, comprising:
an inverter circuit (4) having at least one leg (41u, 41v, 41w) in which two switch units switched between an ON state, which is a conductive state, and an OFF state, which is a non-conductive state, are connected in series between a high-potential line (6a) and a low-potential line (6b), and in which a connection point (42u, 42v, 42w) of the two switch units is an AC input/output point; and
the drive circuit according to [A15] provided for each of the two switch units,
wherein each of the two switch units has:
the first switching element (21); and
the second switching element (22) connected in parallel with the first switching element.

### [A18]

A vehicle, comprising:
the power conversion device according to [A17]; and a motor driven by the power conversion device.

### [A19] (Third Embodiment, FIG. 16)

The signal generation circuit according to any one of [A1] to [A7], wherein the delay signal generation unit (10B) is configured to generate a first delayed pulse signal for the first switching element and two second delayed pulse signals for two of the second switching elements (22A, 22B),
the logic synthesis unit (16B) is configured to generate the first control pulse signal and two second control pulse signals for the two second switching elements by performing logic synthesis operations on three signal sets among the plurality of signal sets defined by the first delayed pulse signal, the two second delayed pulse signals, and the input pulse signal,
the logic synthesis unit performs different logic synthesis operations on at least two of the three signal sets,
a second-a delayed pulse signal among the two second delayed pulse signals is different from the first delayed pulse signal and is a signal for a second-a switching element among the two second switching elements,
a second-b delayed pulse signal among the two second delayed pulse signals is different from the first delayed pulse signal and the second-a delayed pulse signal and is a signal for a second-b switching element among the two second switching elements,
a second-a control pulse signal among the two second control pulse signals is a signal for the second-a switching element,
a second-b control pulse signal among the two second control pulse signals is a signal for the second-b switching element,
the second-a control pulse signal and the second-b control pulse signal are signals that control the second-a switching element and the second-b switching element such that the ON-state periods of the second-a switching element and the second-b switching element are shorter than an ON-state period of the first switching element and an ON-state period of the second-b switching element occurs after an ON-state period of the second-a switching element, and
the first control pulse signal is a signal for controlling the first switching element such that the first switching element transitions from an OFF state to an ON state during the ON-state period of the second-a switching element and the first switching element transitions from the ON state to the OFF state during the ON-state period of the second-b switching element.

### [A20] (Third Embodiment, FIG. 16)

The signal generation circuit according to [A19], wherein the delay signal generation unit (16B) has:
a first delay circuit (11A) that generates the first delayed pulse signal;
a second-a delay circuit (11C) that generates the second-a delayed pulse signal; and
a second-b delay circuit (11D) that generates the second-b delayed pulse signal,
wherein the first delay circuit has:
   a first parallel circuit (12A) having a first end (12c) to which the input pulse signal is input and a second end (12d) electrically connected to the logic synthesis unit, in which a first series circuit (13A) of a first diode (131a) and a first resistor (132a) and a second series circuit (14A) of a second diode (141a) and a second resistor (142a) are connected in parallel; and
   a first capacitor (15a) electrically connected between the second end and ground,
   wherein an anode of the first diode is connected to the first end,
   the first resistor is disposed between a cathode of the first diode and the second end,
   an anode of the second diode is connected to the second end, and
   the second resistor is disposed between a cathode of the second diode and the first end,
wherein the second-a delay circuit has:
   a second-a parallel circuit (12C) having a third-a end (121a) to which the input pulse signal is input and a third-b end (121b) electrically connected to the logic synthesis unit, in which a third-a series circuit (13B) of a third-a diode (131b) and a third-a resistor (132b) and a third-b diode (141b) are connected in parallel; and
   a second-a capacitor (15b) electrically connected between the third-b end and ground,
   wherein an anode of the third-a diode is connected to the third-a end,
   the third-a resistor is disposed between a cathode of the third-a diode and the third-b end,
   a cathode of the third-b diode is connected to the third-a end, and an anode of the third-b diode is connected to the third-b end, and
wherein the second-b delay circuit has:
   a second-b parallel circuit (12D) having a third-c end (122a) to which the input pulse signal is input and a third-d end (122b) electrically connected to the logic synthesis unit, in which a third-b series circuit (14B) of a third-c diode (141b) and a third-b resistor (142b) and a third-d diode (131b) are connected in parallel; and
   a second-b capacitor (15b) electrically connected between the third-d end and ground,
   wherein an anode of the third-d diode is connected to the third-c end, and a cathode of the third-d diode is connected to the third-d end,
   an anode of the third-c diode is connected to the third-d end, and
   the third-b resistor is disposed between a cathode of the third-c diode and the third-c end.

### [A21] (Third Embodiment, FIG. 16)

The signal generation circuit according to [A19] or [A20], wherein the logic synthesis unit (16B) has:
an AND circuit (161) that receives the first delayed pulse signal and the input pulse signal as inputs and outputs the first control pulse signal;
a first XOR circuit (163a) that receives the second-a delayed pulse signal and the input pulse signal as inputs and outputs the second-a control pulse signal; and
a second XOR circuit (163b) that receives the second-b delayed pulse signal and the input pulse signal as inputs and outputs the second-b control pulse signal.

### [A22] (Third Embodiment, FIG. 16)

A drive circuit, comprising:
the signal generation circuit (100B) according to any one of [A19] to [A21];
a first driver (54a) that generates a first output pulse signal for driving the first switching element in response to the first control pulse signal generated by the signal generation circuit;
a second-a driver (541a) that generates a second-a output pulse signal for driving the second-a switching element (22A) in response to the second-a control pulse signal generated by the signal generation circuit; and
a second-b driver (541b) that generates a second-b output pulse signal for driving the second-b switching element in response to the second-b control pulse signal generated by the signal generation circuit.

### [A23] (Third Embodiment, FIG. 16)

The drive circuit according to [A22], comprising: a first push-pull circuit (55a) that is driven by the first output pulse signal and generates a first drive pulse signal for driving the first switching element;
a second-a push-pull circuit (551a) that is driven by the second-a output pulse signal and generates a second-a drive pulse signal for driving the second-a switching element; and
a second-b push-pull circuit (551b) that is driven by the second-b output pulse signal and generates a second-b drive pulse signal for driving the second-b switching element.

### [A24] (FIG. 1)

A power conversion device, comprising:
an inverter circuit (4) having at least one leg in which two switch units switched between an ON state, which is a conductive state, and an OFF state, which is a non-conductive state, are connected in series between a high-potential line and a low-potential line, and in which a connection point of the two switch units is an AC input/output point; and
the drive circuit according to [A22] or [A23] provided corresponding to each of the two switch units,
wherein each of the two switch units has:
the first switching element; and
the second-a switching element and the second-b switching element connected in parallel with the first switching element.

### [A25]

A vehicle, comprising:
the power conversion device according to [A24]; and a motor driven by the power conversion device.

### REFERENCE SIGNS LIST

1 Power conversion device
2 Motor (rotating electrical machine)
4 Inverter circuit
5, 5A, 5B, 5C, 5D, 5E Drive circuit
6a High-potential line
6b Low-potential line
10, 10A, 10B Delay signal generation unit
11, 11E Delay circuit
11A First delay circuit
11B Second delay circuit
11C Second-a delay circuit
11D Second-b delay circuit
12 Parallel circuit (resistance unit)
12A First parallel circuit (resistance unit)
12B Second parallel circuit (resistance unit)
12C Second-a parallel circuit
12D Second-b parallel circuit
12a, 12c Node (first end)
12b, 12d Node (second end)
12e Node (third end)
12f Node (fourth end)
13, 13A First series circuit
13B Third series circuit (third-a series circuit)
14, 14A Second series circuit
14B Fourth series circuit (third-b series circuit)
15, 15c, 43 Capacitor
15a First capacitor
15b Second capacitor (second-a capacitor)
15b Second capacitor (second-b capacitor)
16, 16A, 16B Logic synthesis unit
20, 20A, 20B, 20C, 20D, 20E Switch unit
21, 21A, 21A1, 21A2, 21A3 First switching element
22 Second switching element
22A Second-a switching element
22B Second-b switching element
22A 1, 22A2, 22A 3, 22C1, 22C2, 22C3, 22C 4 Second switching element
41u, 41v, 41w Leg
42u, 42v, 42w Node (connection point)
55a, 55a1, 55a2, 55a3 First push-pull circuit
55b, 55b1, 55b2, 55b3 Second push-pull circuit
100, 100A, 100B, 100C Signal generation circuit
121a Node (third-a end)
121b Node (third-b end)
122a Node (third-c end)
122b Node (third-d end)
131, 131a First diode
131b Third diode (third-a diode)
131b Third diode (third-c diode)
132 Resistor
132a First resistor
132b Third resistor (third-a resistor)
132c Resistor
141, 141a Second diode
141b Fourth diode (third-b diode)
141b Fourth diode (third-d diode)
142, 142a Second resistor
142b Fourth resistor (third-b resistor)
161 AND circuit
162 OR circuit
163 XOR circuit
163a First XOR circuit
163b Second XOR circuit
551a Second-a push-pull circuit
551b Second-b push-pull circuit
54a, 54a1, 54a2, 54a3 First GDIC (first driver)
54b, 54b1, 54b2, 54b3 Second GDIC (second driver)
541a Second-a GDIC (second-a driver)
541b Second-b GDIC (second-b driver)
S1 Input pulse signal
S2 Delayed pulse signal
S2a First delayed pulse signal
S2b Second delayed pulse signal
S2b1 Second-a delayed pulse signal
S2b2 Second-b delayed pulse signal
S3 First control pulse signal
S4 Second control pulse signal
S4a Second-a control pulse signal
S4b Second-b control pulse signal
X Vehicle.

What is claimed is:

1. A signal generation circuit, comprising:
a delay signal generation unit configured to generate at least one delayed pulse signal using a common input pulse signal for a first switching element and a second switching element having different transition times between an ON state, which is a conductive state, and an OFF state, which is a non-conductive state; and
a logic synthesis unit configured to generate a first control pulse signal for the first switching element and a second control pulse signal for the second switching element by performing different logic synthesis operations on two signal sets among a plurality of signal sets defined by the at least one delayed pulse signal and the input pulse signal,
wherein the first control pulse signal is different from the input pulse signal, and
the second control pulse signal is different from the input pulse signal and the first control pulse signal.

2. The signal generation circuit according to claim 1, wherein the delay signal generation unit has at least one delay circuit including a resistor and a capacitor.

3. The signal generation circuit according to claim 1, wherein the delay signal generation unit has at least one delay circuit, and
the delay circuit has:
a resistance unit configured to have two signal paths connected in parallel and to have resistances respectively for delaying a rising edge and delaying a falling edge of a pulse of the input pulse signal; and
a capacitor.

4. The signal generation circuit according to claim 1, wherein the logic synthesis unit has at least two of an AND circuit, an OR circuit, and an XOR circuit in order to perform the different logic synthesis operations.

5. The signal generation circuit according to claim 1, wherein the second switching element is a switching element having a shorter transition time than the first switching element.

6. The signal generation circuit according to claim 1, wherein the first switching element is an insulated gate bipolar transistor, and
the second switching element is a metal-oxide-semiconductor field-effect transistor.

7. The signal generation circuit according to claim 1, wherein the logic synthesis unit is configured to generate the first control pulse signal and the second control pulse signal such that the second switching element turns on before the first switching element turns on and the second switching element turns off after the first switching element turns off.

8. The signal generation circuit according to claim 1, wherein the delay signal generation unit has a delay circuit that generates the delayed pulse signal,
the two signal sets are a set of the delayed pulse signal and the input pulse signal or a set of the delayed pulse signals, and
the logic synthesis unit is:
configured to generate the second control pulse signal based on a set of the delayed pulse signal and the input pulse signal or a set of the delayed pulse signals when generating the first control pulse signal based on a set of the delayed pulse signal and the input pulse signal; and
configured to generate the second control pulse signal based on a set of the delayed pulse signal and the input pulse signal when generating the first control pulse signal based on a set of the delayed pulse signals.

9. The signal generation circuit according to claim 8, wherein the delay circuit has:
a parallel circuit in which a first series circuit of a first diode and a first resistor and a second series circuit of a second diode and a second resistor are connected in parallel, the parallel circuit having a first end to which the input pulse signal is input and a second end electrically connected to the logic synthesis unit; and
a first capacitor electrically connected between the second end and ground,
wherein an anode of the first diode is electrically connected to the first end,
the first resistor is disposed between a cathode of the first diode and the second end,
an anode of the second diode is electrically connected to the second end, and
the second resistor is disposed between a cathode of the second diode and the first end.

10. The signal generation circuit according to claim 9, wherein the logic synthesis unit has:
an AND circuit that receives the delayed pulse signal and the input pulse signal as inputs and outputs the first control pulse signal; and
an OR circuit that receives the delayed pulse signal and the input pulse signal as inputs and outputs the second control pulse signal.

11. The signal generation circuit according to claim 1, wherein the logic synthesis unit is configured to generate the first control pulse signal and the second control pulse signal such that the first switching element turns on in a first ON state among two ON states of the second switching element and the first switching element turns off in a second ON state, which is after the first ON state, among the two ON states of the second switching element.

12. The signal generation circuit according to claim 1, wherein the delay signal generation unit has:
a first delay circuit that generates a first delayed pulse signal; and
a second delay circuit that generates a second delayed pulse signal different from the first delayed pulse signal, and
the logic synthesis unit is configured to generate the first control pulse signal based on a set of the first delayed pulse signals and generates the second control pulse signal based on a set of the second delayed pulse signal and the input pulse signal.

13. The signal generation circuit according to claim 12, wherein the first delay circuit has:
a first parallel circuit having a first end to which the input pulse signal is input and a second end electrically connected to the logic synthesis unit, in which a first series circuit of a first diode and a first resistor and a second series circuit of a second diode and a second resistor are connected in parallel; and
a first capacitor electrically connected between the second end and ground,
wherein an anode of the first diode is connected to the first end,
the first resistor is disposed between a cathode of the first diode and the second end,
an anode of the second diode is connected to the second end, and
the second resistor is disposed between a cathode of the second diode and the first end, and
the second delay circuit has:
a second parallel circuit having a third end to which the input pulse signal is input and a fourth end electrically connected to the logic synthesis unit, in which a third series circuit of a third diode and a third resistor and a fourth series circuit of a fourth diode and a fourth resistor are connected in parallel; and
a second capacitor electrically connected between the fourth end and ground,
wherein an anode of the third diode is connected to the third end,
the third resistor is disposed between a cathode of the third diode and the fourth end,
an anode of the fourth diode is connected to the fourth end, and
the fourth resistor is disposed between a cathode of the fourth diode and the third end.

14. The signal generation circuit according to claim 12, wherein the logic synthesis unit has:
an AND circuit that receives two of the first delayed pulse signals as inputs and outputs the first control pulse signal; and
an XOR circuit that receives the second delayed pulse signal and the input pulse signal as inputs and outputs the second control pulse signal.

15. A drive circuit, comprising:
the signal generation circuit according to claim 1;
a first driver that generates a first output pulse signal for driving the first switching element in response to the first control pulse signal generated by the signal generation circuit; and
a second driver that generates a second output pulse signal for driving the second switching element in response to the second control pulse signal generated by the signal generation circuit.

16. The drive circuit according to claim 15, comprising:
a first push-pull circuit that is driven by the first output pulse signal and generates a first drive pulse signal for driving the first switching element; and
a second push-pull circuit that is driven by the second output pulse signal and generates a second drive pulse signal for driving the second switching element.

17. A power conversion device, comprising:
an inverter circuit having at least one leg in which two switch units switched between an ON state, which is a conductive state, and an OFF state, which is a non-conductive state, are connected in series between a high-potential line and a low-potential line, and in which a connection point of the two switch units is an AC input/output point; and
the drive circuit according to claim 15 provided for each of the two switch units,
wherein each of the two switch units has:
the first switching element; and
the second switching element connected in parallel with the first switching element.

18. A vehicle, comprising:
the power conversion device according to claim 17; and
a motor driven by the power conversion device.
